(19) United States
(12) Patent Application Publication
(10) Pub. No.: US 2017/0092875 A1
(43) Pub. Date: Mar. 30, 2017

(54) ORGANIC ELECTROLUMINESCENT DEVICE

(71) Applicant: Merck Patent GmbH, Darmstadt (DE)

(72) Inventors: Amir Hossain PARHAM, Frnakfurt Am Main (DE); Philipp STOESSEL, Frankfurt Am Main (DE); Chrisof PFLLUMM, Darmstadt (DE); Anja JATSCH, Frankfurt Am Main (DE); Joachim KAISER, Darmstadt (DE)

(21) Appl. No.: 15/126,478

(22) PCT Filed: Feb. 19, 2015
(86) PCT No.: PCT/EP2015/000379

§ 371 Date: Sep. 15, 2016

(30) Foreign Application Priority Data
Mar. 18, 2014 (EP) 14001002.6

(51) Int. Cl. H01L 51/00; C09K 11/06; C09K 11/02

(52) U.S. Cl. CPC H01L 51/0072; H01L 51/0077; H01L 51/006; H01L 51/0067; H01L 51/0056; H01L 51/0058; H01L 51/0074; H01L 51/0054; H01L 51/0073; C09K 11/02; C09K 11/06; H01L 51/5221

(57) ABSTRACT

The invention relates to organic electroluminescent devices containing cathodes, anodes and an emitting layer, containing a luminescent organic compound which is at a distance between the lowest triple state (T1) and the first excited single state (S1) of =0.15 eV (TADF-compound), and an organic compound with at least one triphenylene group and/or aza triphenylene group which comprise up to six aza-atoms (TP-compound).

The present invention relates to organic electroluminescent devices comprising mixtures of a luminescent material having a small singlet-triplet gap and matrix materials having at least one triphenylene group and/or azatriphenylene group having up to six aza nitrogen atoms (TP compound).

The structure of organic electroluminescent devices (OLEDs) in which organic semiconductors are used as functional materials is described, for example, in U.S. Pat. No. 4,539,507, U.S. Pat. No. 5,151,629, EP 0676461 and WO 98/27136. Emitting materials used here are especially also organometallic iridium and platinum complexes which exhibit phosphorescence rather than fluorescence (M. A. Baldo et al., Appl. Phys. Lett. 1999, 75, 4-6). For quantum-mechanical reasons, up to four times the energy efficiency and power efficiency is possible using organometallic compounds as phosphorescent emitters.

In spite of the good results which are achieved with organometallic iridium and platinum complexes, however, they also have a number of disadvantages: for instance, iridium and platinum are scarce and costly metals. It would therefore be desirable for conservation of resources to be able to avoid the use of these scarce metals. Furthermore, some metal complexes of this kind have lower thermal stability than purely organic compounds, and so it would be advantageous for this reason too to use purely organic compounds, if they lead to comparably good efficiencies. Furthermore, iridium or platinum emitters that phosphoresce in the blue, especially deep blue, and have high efficiency and lifetime are technically difficult to achieve at present, and so there is a need for improvement here too. Furthermore, there is a need for improvement especially in the case of the lifetime of phosphorescent OLEDs containing Ir or Pt emitters when the OLED is operated at relatively high temperature, as required for some applications.

An alternative development is the use of emitters which exhibit thermally activated delayed fluorescence (TADF) (e.g. H. Uoyama et al., Nature 2012, vol. 492, 234). These are organic materials in which the energy gap between the lowest triplet state T₁ and the first excited singlet state S₁ is so small that this energy gap is smaller than or in the region of the thermal energy. For quantum-statistical reasons, on electronic excitation in the OLED, 75% of the excited states are in the triplet state and 25% in the singlet state. Since purely organic molecules cannot usually emit from the triplet state, 75% of the excited states cannot be utilized for emission, as a result of which it is possible in principle to convert only 25% of the excitation energy to light. If, however, the energy gap between the lowest triplet state and the lowest excited singlet state is not greater or not significantly greater than the thermal energy which is described by kT, the first excited singlet state of the molecule is accessible from the triplet state by thermal excitation and can be populated thermally. Since this singlet state is an emissive state from which fluorescence is possible, this state can be used to generate light. Thus, in principle, the conversion of up to 100% of the electrical energy to light is possible when purely organic materials are used as emitter. Thus, the prior art describes an external quantum efficiency of more than 19%, which is within the same order of magnitude as for phosphorescent OLEDs. It is thus possible with purely organic materials of this kind to achieve very good efficiencies and at the same time to avoid the use of scarce metals such as iridium or platinum. In addition, it is also possible with such materials to achieve high-efficiency blue-emitting OLEDs.

In the prior art, emitters that exhibit thermally activated delayed fluorescence (called TADF compound hereinafter) are used in combination with various matrix materials, for example with carbazole derivatives (H. Uoyama et al., Nature 2012, 492, 234; Endo et al., Appl. Phys. Lett. 2011, 98, 083302; Nakagawa et al., Chem. Commun. 2012, 48, 9580; Lee et al., Appl. Phys. Lett. 2012, 101, 093306/1), phosphine oxide-dibenzothiophene derivatives (H. Uoyama et al., Nature 2012, 492, 234) or silane derivatives (Mehes et al., Angew. Chem. Int. Ed. 2012, 51, 11311; Lee et al., Appl. Phys. Lett. 2012, 101, 093306/1).

Generally speaking, there is still further need for improvement in organic electroluminescent devices that exhibit emission by the TADF mechanism, especially with regard to efficiency, voltage and lifetime.

The technical object underlying the present invention is thus that of providing OLEDs having TADF-based emission and having improved properties, especially in relation to one or more of the properties mentioned.

The object is surprisingly achieved by organic electroluminescent devices and processes as claimed in the claims.

The invention provides an organic electroluminescent device comprising cathode, anode and emitting layer, comprising the following compounds:
(A) at least one luminescent organic compound having a gap between the lowest triplet state T₁ and the first excited singlet state S₁ of ≦0.15 eV (TADF compound); and
(B) at least one organic compound having at least one triphenylene group and/or azatriphenylene group having up to six aza nitrogen atoms (TP compound).

There follows a detailed description of the luminescent organic compound having a gap between the lowest triplet state T₁ and the first excited singlet state S₁ of ≦0.15 eV. This is a compound which exhibits TADF (thermally activated delayed fluorescence). This compound is referred to in the description which follows as “TADF compound”.

An organic compound in the context of the present invention is a carbonaceous compound that does not contain any metals. More particularly, the organic compound is formed from the elements C, H, D, B, Si, N, P, O, S, F, Cl, Br and I.

A luminescent compound in the context of the present invention is a compound capable of emitting light at room temperature under optical excitation in an environment as exists in the organic electroluminescent device. This compound preferably has a luminescence quantum efficiency (photoluminescence quantum efficiency) of at least 40%, more preferably of at least 50%, even more preferably of at least 60% and especially preferably of at least 70%. The luminescence quantum efficiency is determined in a mixed layer with the matrix material like that which is to be used in the organic electroluminescent device. The way in which the determination of the luminescence quantum efficiency is conducted in the context of the present invention is described in a general and detailed manner in the examples section.

It is additionally preferable when the TADF compound has a short decay time. The decay time is preferably ≦50 ρs, more preferably <20 μs, even more preferably <10 μs. The way in which the determination of the decay time is conducted in the context of the present invention is described in a general and detailed manner in the examples section.

The energy of the lowest excited singlet state (S₁) and the lowest triplet state (T₁) are determined by quantum-chemical calculation. The way in which this determination is conducted in the context of the present invention is described in a general and detailed manner in the examples section.

As described above, the gap between S₁ and T₁ must be no more than 0.15 eV, in order that the compound is a TADF compound in the sense of the present invention. Preferably, the gap between S₁ and T₁ is ≦0.10 eV, more preferably ≦0.08 eV, most preferably ≦0.05 eV.

The TADF compound is preferably an aromatic compound having both donor and acceptor substituents, with only slight spatial overlap between the LUMO and the HOMO of the compound. What is understood by donor and acceptor substituents is known in principle to those skilled in the art. In a preferred embodiment, the donor substituent is electron-donating and exerts a +M effect (positive mesomeric effect).

Suitable donor substituents especially have an atom having a free electron pair such as an N, S or O atom. Preference is given to 5-membered heteroaryl groups having exactly one ring heteroatom, to which further aryl groups may also be fused. Preference is given especially to carbazole groups or carbazole derivatives, each preferably bonded to the aromatic compound via N. These groups may also have further substitution. Suitable donor substituents are additionally also diaryl- or heteroarylamino groups.

Suitable acceptor substituents are especially cyano groups, but also, for example, electron-deficient heteroaryl groups, for example triazine, which may also have further substitution. In a preferred embodiment, the acceptor substituent is electron-withdrawing and exerts a −M effect (negative mesomeric effect).

In a preferred embodiment, the TADF compound has an aromatic ring structure having at least one heteroaryl group and at least one N as heteroatom, preferably selected from carbazole, azaanthracene and triazine; and/or the TADF compound has at least one aryl group, especially a benzene group, substituted by at least one cyano group, especially by one, two or three cyano groups.

In the mixture of TADF compound and TP compound, the TP compound is regarded as the matrix. In order to avoid exciplex formation in the emitting layer, it is preferable when the following condition applies to LUMO(TADF), i.e. the LUMO of the TADF compound, and the HOMO(matrix), i.e. the HOMO of the TP compound:

LUMO(TADF)−HOMO(matrix)>S₁(TADF)−0.4 eV;

more preferably:

LUMO(TADF)−HOMO(matrix)>S₁(TADF)−0.3 eV;

and even more preferably:

LUMO(TADF)−HOMO(matrix)>S₁(TADF)−0.2 eV.

S₁(TADF) here is the first excited singlet state S₁ of the TADF compound.

The general art knowledge of the person skilled in the art includes knowledge of which materials are generally suitable as TADF compounds. The following references disclose, by way of example, materials that are potentially suitable as TADF compounds:
Tanaka et al., Chemistry of Materials 25(18), 3766 (2013)
Lee et al., Journal of Materials Chemistry C 1(30), 4599 (2013)
Zhang et al., Nature Photonics advance online publication, 1 (2014), doi: 10.1038/nphoton.2014.12
Serevicius et al., Physical Chemistry Chemical Physics 15(38), 15850 (2013)
Li et al., Advanced Materials 25(24), 3319 (2013)
Youn Lee et al., Applied Physics Letters 101(9), 093306 (2012)
Nishimoto et al., Materials Horizons 1, 264 (2014), doi: 10.1039/C3MH00079F
Valchanov et al., Organic Electronics, 14(11), 2727 (2013)
Nasu et al., ChemComm, 49, 10385 (2013)

In addition, the following patent applications contain potential TADF compounds: WO 2013/154064, WO 2013/133359, WO 2013/161437, WO 2013/081088, WO 2013/081088, WO 2013/011954, JP 2013/116975 and US 2012/0241732.

In addition, the person skilled in the art is able to infer design principles for TADF compounds from these publications. For example, Valchanov et al. show how the color of TADF compounds can be adjusted.

Examples of suitable TADF compounds are the structures shown in the following table:

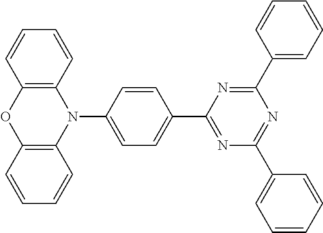 [SMILES: c1ccc(-c2nc(-c3ccccc3)nc(-c3ccc(N4c5ccccc5Oc5ccccc54)cc3)n2)cc1]

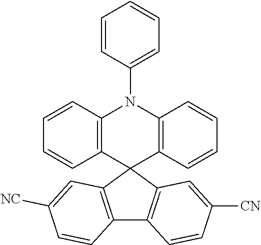 [SMILES: N#Cc1ccc2c(c1)C1(c3cc(C#N)ccc3-2)c2ccccc2N(c2ccccc2)c2ccccc21]

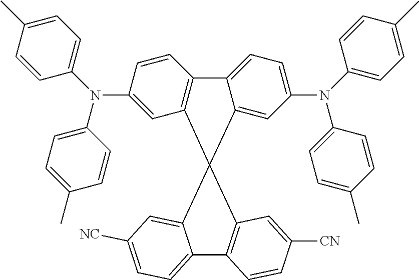

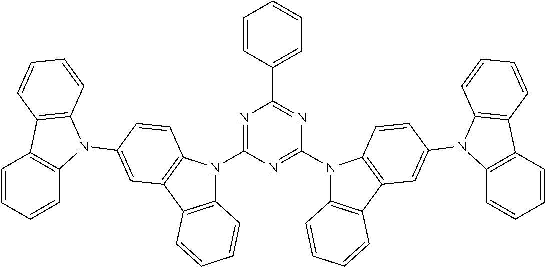 [SMILES: c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1]

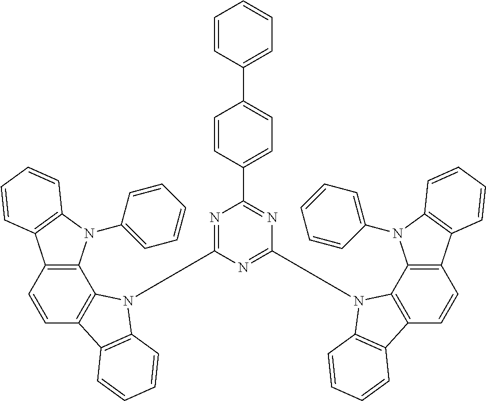 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1]

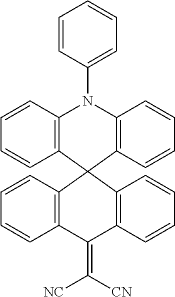 [SMILES: N#CC(C#N)=C1c2ccccc2C2(c3ccccc31)c1ccccc1N(c1ccccc1)c1ccccc12]

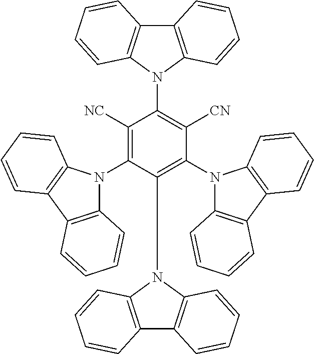 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

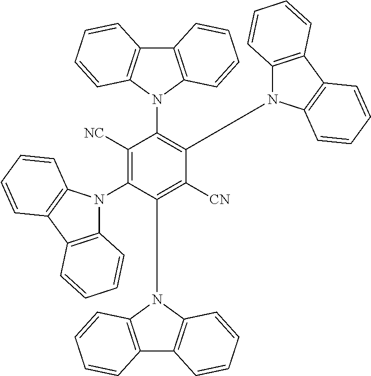 [SMILES: N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21]

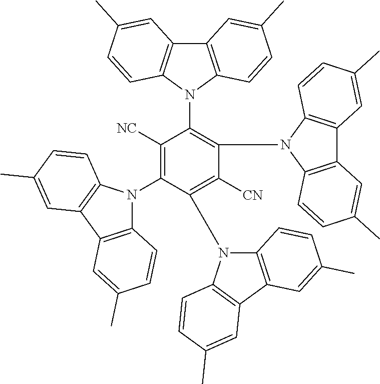

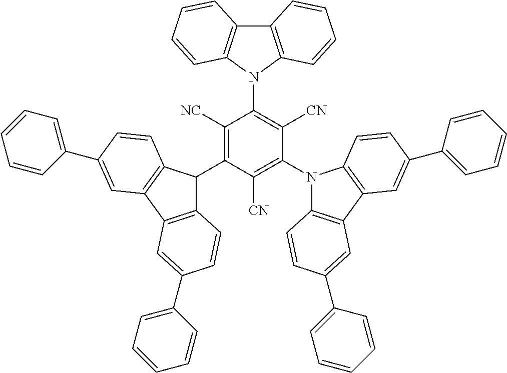 [SMILES: N#Cc1c(C2c3ccc(-c4ccccc4)cc3-c3cc(-c4ccccc4)ccc32)c(C#N)c(-n2c3ccc(-c4ccccc4)cc3c3cc(-c4ccccc4)ccc32)c(C#N)c1-n1c2ccccc2c2ccccc21]

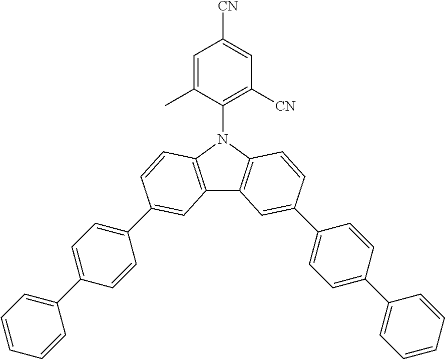 [SMILES: Cc1cc(C#N)cc(C#N)c1-n1c2ccc(-c3ccc(-c4ccccc4)cc3)cc2c2cc(-c3ccc(-c4ccccc4)cc3)ccc21]

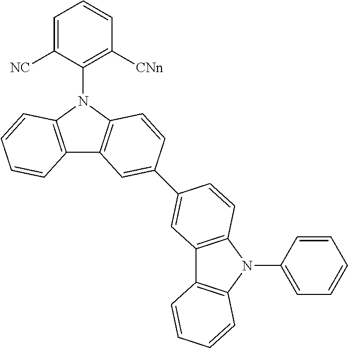

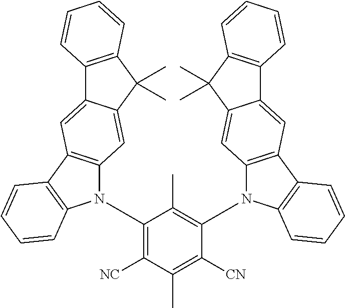 [SMILES: Cc1c(C#N)c(-n2c3ccccc3c3cc4c(cc32)C(C)(C)c2ccccc2-4)c(C)c(-n2c3ccccc3c3cc4c(cc32)C(C)(C)c2ccccc2-4)c1C#N]

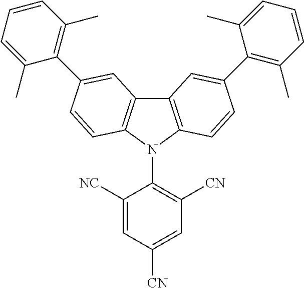 [SMILES: Cc1cccc(C)c1-c1ccc2c(c1)c1cc(-c3c(C)cccc3C)ccc1n2-c1c(C#N)cc(C#N)cc1C#N]

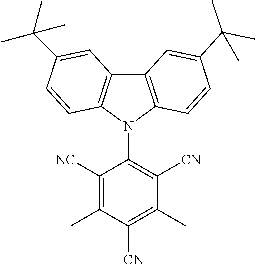 [SMILES: Cc1c(C#N)c(C)c(C#N)c(-n2c3ccc(C(C)(C)C)cc3c3cc(C(C)(C)C)ccc32)c1C#N]

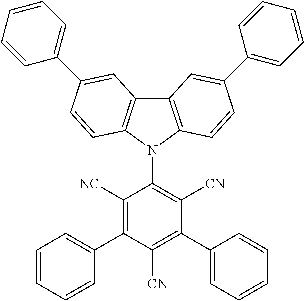 [SMILES: N#Cc1c(-c2ccccc2)c(C#N)c(-n2c3ccc(-c4ccccc4)cc3c3cc(-c4ccccc4)ccc32)c(C#N)c1-c1ccccc1]

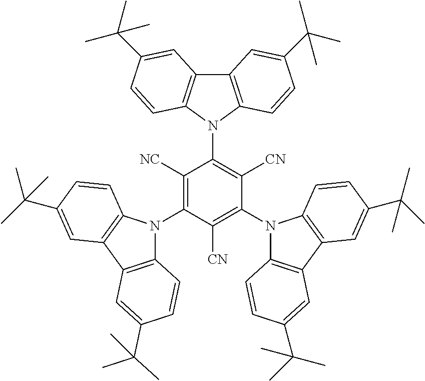 [SMILES: CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(C#N)c(-n2c3ccc(C(C)(C)C)cc3c3cc(C(C)(C)C)ccc32)c1C#N]

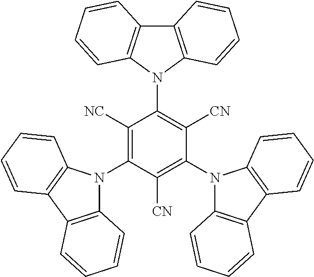 [SMILES: N#Cc1c(-n2c3ccccc3c3ccccc32)c(C#N)c(-n2c3ccccc3c3ccccc32)c(C#N)c1-n1c2ccccc2c2ccccc21]

In a preferred embodiment of the invention, the TP compound is the matrix material for the TADF compound. The TADF compound is the emitting compound in the mixture, i.e. the compound whose emission is observed from the emitting layer, while the TP compound, which serves as matrix material, contributes only insignificantly, if at all, to the emission of the mixture.

In a preferred embodiment of the invention, the emitting layer consists solely of the TP compound and the TADF compound. In a further embodiment of the invention, the emitting layer comprises one or more further compounds apart from the TP compound and the TADF compound.

In order that the TADF compound is the emitting compound in the mixture of the emitting layer, it is preferable that the lowest triplet energy of the TP compound is not more than 0.1 eV lower than the lowest triplet energy of the TADF compound. Especially preferably, T₁(matrix)≧T₁(TADF), More preferably: T₁(matrix)−T₁(TADF)≧0.1 eV, most preferably T₁(matrix)−T₁(TADF)≧0.2 eV. T₁(matrix) here is the lowest triplet energy of the TP compound and T₁(TADF) is the lowest triplet energy of the TADF compound. The lowest triplet energy of the matrix is determined here by quantum-chemical calculation, as described in general terms in the examples section at the back.

The organic electroluminescent device of the invention contains at least one organic compound having at least one triphenylene group and/or azatriphenylene group having up to six aza atoms. These compounds are referred to in the context of this application as “TP compounds”.

Triphenylene (CAS 217-59-4; benzo[I]phenanthrene; C₁₈H₁₂) is a polycyclic aromatic hydrocarbon composed of four benzene rings.

Monoazatriphenylene is a corresponding heterocyclic aromatic compound in which one of the C—H groups in the triphenylene group is replaced by a nitrogen atom (C₁₇H₁₁N). According to the invention, the azatriphenylenes may have up to six aza atoms in the central triphenylene group. Azatriphenylenes having two or more aza atoms in the triphenylene group may be referred to as polyazatriphenylenes. The azatriphenylene group is more preferably a monoazatriphenylene group or a diazatriphenylene group. It may also be a triaza-, tetraaza-, pentaaza- or hexaazatriphenylene group.

In the TP compound of the invention, the triphenylene group or the azatriphenylene group is substituted. It is also possible for further aromatic rings, especially benzene rings, to be present as substituents, these being fused to the triphenylene group and/or azatriphenylene group. The organic compound may therefore have a triphenylene group which is part of a polycyclic aromatic structure having more than four rings. For example, the TP compound may have one or more benzene rings fused to the central triphenylene group and/or azatriphenylene group. Aromatic rings are fused here such that they have two carbon atoms in common, i.e. a common edge, with the triphenylene group and/or azatriphenylene group. In chemical nomenclature, such ring systems having a triphenylene group and further fused benzene rings or other aromatic groups are partly named in accordance with a higher base structure, such as chrysene, pyrene, tetraphenylene or trinaphthylene. Such compounds are TP compounds in the context of the invention when they simultaneously have a triphenylene group (triphenylene structural unit). This applies analogously to TP compounds of the invention having an azatriphenylene group.

In a preferred embodiment of the invention, the TP compound has the formula (1) or (2):

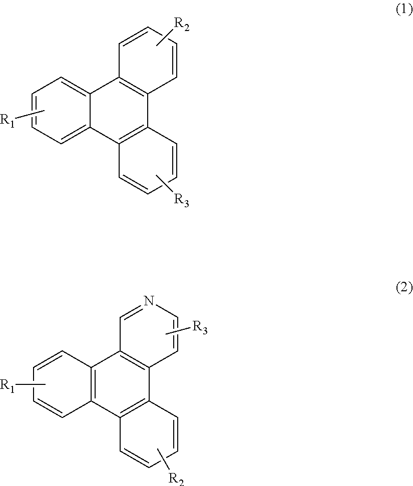

or wherein the TP compound corresponds to the formula (2) and has up to five further aza nitrogen atoms which replace C—H groups in the monoazatriphenylene group shown in formula (2),
where the R₁, R₂ and R₃ radicals are selected independently of one another,
where no, one or more R₁, R₂ or R₃ radicals may be present in each case, where two or more radicals of R₁, of R₂ or of R₃ are selected independently of one another,
where the R₁, R₂ or R₃ radicals are selected from
   (i) an aromatic group which forms a conjugated system with the triphenylene group or azatriphenylene group, where the aromatic group has 5 to 80 aromatic ring atoms which may be substituted by one or more R₄ radicals, where R₄ is independently selected from H, D, F, Cl, Br, unbranched alkyl having 1 to 20 carbon atoms, or branched or cyclic alkyl having 3 to 20 carbon atoms, where two or more R₄ radicals may be joined to one another and may form a ring, and
   (ii) an alkyl radical R₅ selected from unbranched alkyl having 1 to 20 carbon atoms, branched or cyclic alkyl having 3 to 20 carbon atoms, where two R₅ radicals may be joined to one another and may form a ring,

with the proviso that at least one R₁, R₂ or R₃ radical which is an aromatic group (i) is present.

Each compound of the formula (1) or (2) has at least four aromatic rings that are part of the triphenylene or azatriphenylene base structure (group). The base structure has four fused rings in each case, where the three outer rings and one inner ring may be different. The four rings form an aromatic system. The R₁, R₂ and R₃ radicals are substituents of the outer rings. The R₁, R₂ and R₃ radicals are selected independently of one another. Each outer ring may have no, one or more radicals as substituents. At the same time, any outer ring may have two, three or four substituents which may be identical to one another or different than one another. According to the invention, an outer ring usually has no or only a single R₁, R₂ or R₃ radical.

The compounds may correspond to the formula (2) and additionally have up to five further aza nitrogen atoms which replace C—H groups of the monoazatriphenylene group shown in formula (2), i.e. have a total of up to six aza nitrogen atoms. Such compounds having two or more aza nitrogen atoms have a polyazatriphenylene group. In this case, it is not ruled out that the R₁, R₂ and R₃ radicals have further aza nitrogen atoms. It is preferable in accordance with the invention that the compound of the formula (2) has a monoazatriphenylene group.

At least one R₁, R₂ and R₃ radical has an aromatic group. At the same time, the radical R₁, R₂ or R₃ may consist of the aromatic group, or the R₁, R₂ or R₃ radical may additionally have at least one further nonaromatic group. The aromatic group together with the triphenylene group or azatriphenylene group forms a higher conjugated system which is a conjugated aromatic system. Preferably, all R₁, R₂ and R₃ radicals, if present, have such aromatic groups.

In a preferred embodiment of the invention, an aromatic R₁, R₂ or R₃ group is bonded to the triphenylene group or azatriphenylene group via a conjugated C—C single bond. Aromatic rings or ring systems joined to one another via C—C single bonds are generally regarded as higher aromatic ring systems. The simplest compound of this kind is biphenyl, in which two benzene rings are joined to one another via a C—C single bond, such that the two rings form a conjugated aromatic ring system.

In a further preferred embodiment of the invention, R₁, R₂ and/or R₃ is an aromatic group annelated (fused) to the triphenylene group and/or azatriphenylene group or has such a group. Fused aromatic groups are joined to one another via at least two ring members. Preferably, the fused aromatic group is a benzene ring. Preferably, the organic compound has a total of one or more, for example two, three, four, five or six, further benzene rings fused to the triphenylene group and/or azatriphenylene group to form a polycyclic aromatic compound.

The alkyl radical has preferably 1 to 10 carbon atoms and is especially selected from methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl and n-heptyl. More preferably, the alkyl radical is selected from methyl, ethyl and isopropyl.

The aromatic group may be an aryl group, a heteroaryl group or an aromatic ring system in which two or more aryl and/or heteroaryl groups are joined to one another, more preferably by single bonds. The aromatic group contains preferably 6 to 80 carbon atoms. Preferably in accordance with the invention, an aryl group contains 6 to 80 carbon atoms. An aromatic ring system with a heteroaryl group contains preferably 2 to 80 carbon atoms and at least one heteroatom as a ring constituent, with the proviso that the sum total of carbon atoms and heteroatoms is at least 5. Heteroatoms are preferably selected from N, O, S and/or Se. An aryl group or heteroaryl group is understood to mean either a simple aromatic cycle, i.e. benzene, or a 6-membered heteroaryl ring, such as an azine, for example pyridine, pyrimidine or thiophene, or a fused (annelated) aryl or heteroaryl group, for example naphthalene, anthracene, phenanthrene, quinoline, isoquinoline, etc.

The aromatic group of an R₁, R₂ and R₃ radical may especially have at least one structural unit selected from benzene, naphthalene, biphenyl, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, azines such as pyridine, or quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole. The aromatic group may have a plurality of, for example 2 or 3 of, the structural units mentioned, which may be identical to one another or different than one another. The structural units may be joined or fused to one another via single bonds.

It is preferable that all aromatic rings of the TP compound either form a fused aromatic system or form a higher aromatic ring system in which all rings are joined to one another via single bonds. The TP compound preferably has between 6 and 20 aromatic rings or preferably consists of 6 to 20 aromatic rings. It has been found that the properties of the invention can be achieved particularly well in the case of such a size.

In a preferred embodiment, the entire TP compound forms a conjugated system. This means that no substituents that are not part of the conjugated system are present.

In one embodiment of the invention, at least one R₁, R₂ or R₃ radical is an alkyl radical R₅ selected from unbranched alkyl having 1 to 20 carbon atoms, branched or cyclic alkyl having 3 to 20 carbon atoms, where two R₅ radicals may be joined to one another and may form a ring. The alkyl radical has preferably 1 to 10 carbon atoms and is especially selected from methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl and n-heptyl. More preferably, the alkyl radical is selected from methyl, ethyl, isopropyl and tert-butyl. The TP compound may have one, two or more such alkyl radicals.

In a preferred embodiment of the invention, the TP compound of the formula (1) or (2) has at least one of the following structural units:

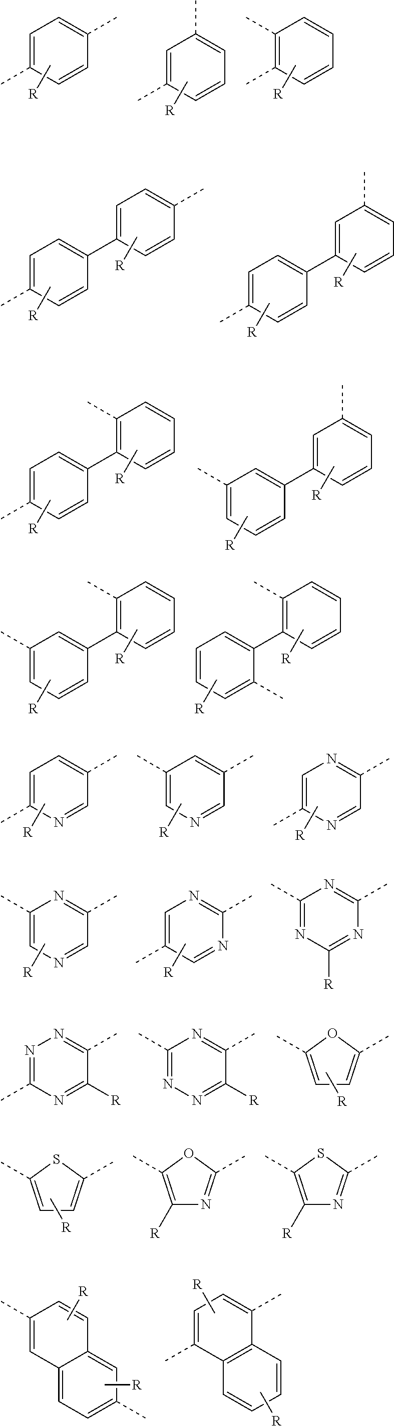

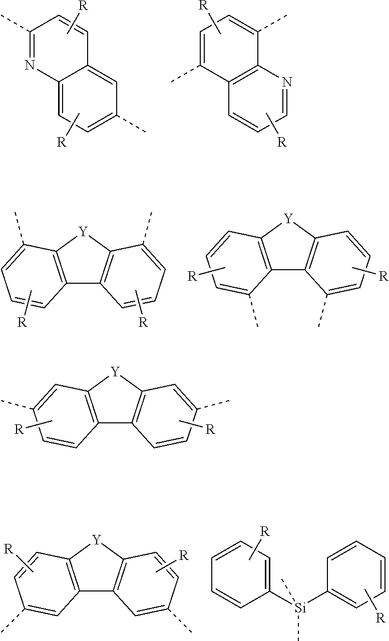

where R is selected as specified for R₄ above, or where R is an aromatic group which may be substituted by one or more R₄ radicals, where Y is selected from C(R₆)₂, NR₆, S, O and Se, where R₆ is selected from H, unbranched alkyl having 1 to 20 carbon atoms, branched or cyclic alkyl having 3 to 20 carbon atoms, and an aromatic group which may be an aryl or heteroaryl group, especially phenyl, where two R₆ radicals may be joined to one another and may form a ring. The dotted lines represent single bonds, preferably C—C single bonds. The single bonds embed the structural units into the TP compound.

In a preferred embodiment of the invention, at least one R₁, R₂ or R₃ radical has a structural unit selected from benzene, naphthalene, biphenyl, benzofuran, benzothiophene, carbazole, azacarbazole, dibenzothiophene, dibenzofuran, triphenylene and azines such as triazine, pyrimidine and pyridine.

In a preferred embodiment of the invention, at least one R₁, R₂ or R₃ radical has an electron-donating group that exerts a +M effect. Such groups or radicals having such groups are also referred to as donor substituents. Suitable donor substituents are especially heteroaryl groups such as carbazole groups. In a preferred embodiment, the donor substituent is an electron-rich heteroaryl group preferably having a 5-membered heterocycle which preferably has exactly one heteroatom selected from N, O, S and Se. More particularly, the R₁, R₂ or R₃ radical is electron-donating and exerts a +M effect.

In a preferred embodiment of the invention, no R₁, R₂ or R₃ radical has an electron-withdrawing group that exerts a −M effect. In this embodiment, the TP compound overall has no such group. Such groups or radicals having such groups are also referred to as acceptor substituents. Acceptor substituents are especially cyano groups, but also, for example, electron-deficient heteroaryl groups which may also have further substitution.

In a preferred embodiment of the invention, a TP compound having at least one electron-donating substituent that exerts a +M effect and having no electron-withdrawing substituent that exerts a −M effect is used.

In a preferred embodiment, the LUMO of the TP compound is less than −2.00 eV.

In a particularly preferred embodiment, the LUMO of the TP compound is less than −2.70 eV, preferably less than −2.80 eV, even more preferably less than −2.85 eV. Such compounds can have particularly high efficiencies. Such relatively low LUMOs can be achieved when the TP compound has at least one suitable electron-withdrawing group, especially an electron-deficient N-containing heterocyclic group, especially an azine group such as pyridine, pyrimidine or triazine.

In a preferred embodiment, the triphenylene group or azatriphenylene group has only fused further aromatic rings bonded to the triphenylene or azatriphenylene group via a single side of the rings. Preferably, no further fused rings bonded to the triphenylene group via two, three or more sides are present.

In a preferred embodiment, the TP compound has a total of 1 to 8, preferably 1 to 6 or 1 to 4 or 2 to 4 heteroatoms, where all heteroatoms in the TP compound are ring constituents of heteroaryl groups. The heteroatoms are preferably selected from N, S and O and in a particularly preferred embodiment are N only.

In a preferred embodiment, only a single R₁, R₂ or R₃ radical in total is present. In a preferred embodiment, this single radical has only a single heteroatom at most.

In one embodiment of the invention, none of the R₁, R₂ and R₃ radicals in the TP compound has a heteroaryl group composed of at least five fused rings having at least one nitrogen atom and in which five rings are joined to one another in a linear manner via one side of the ring in each case. In this embodiment, the TP compound is especially not an indenocarbazole derivative or an indolocarbazole derivative. In this embodiment, the TP compound especially does not have a heteroaryl group composed of five rings in which one or two of the rings are five-membered rings having a heteroatom and the other rings are six-membered rings.

In a preferred embodiment, at least one of the R₁, R₂ or R₃ radicals has a structural unit selected from benzofuran, benzothiophene, dibenzofuran and dibenzothiophene. In this case, it is preferable that one of the structural elements mentioned is bonded to a triphenylene via a C—C single bond. It is possible here for R₁, R₂ or R₃ to have further aryl or heteroaryl groups bonded via single bonds to the benzofuran, benzothiophene, dibenzofuran or dibenzothiophene. Such compounds and the preparation thereof are described in WO 2009/021126. Corresponding compounds are shown by way of example in the formulae (25) to (38) below.

In a further preferred embodiment, the TP compound is a compound of the formula (1) having a triphenylene group, where the R₁, R₂ and R₃ radicals are selected from aryl groups and aromatic ring systems composed of aryl groups. In this embodiment, the TP compound has no heteroatoms. The aryl radicals are preferably benzene radicals. Preferably, two or more benzene radicals are bonded to one another via single bonds. In a preferred embodiment, a central triphenylene group is substituted by a total of two to ten benzene groups, preferably three to six benzene radicals.

Corresponding compounds are described in WO 2009/021107 A2. Corresponding compounds are shown by way of example in the formulae (17) to (24) below.

Further triphenylene compounds in which a central triphenyl group is substituted exclusively by aryl radicals are disclosed in WO 2006/130598 A2. Corresponding compounds are shown by way of example in the formulae (3a), (3b) and (4) to (16) below. In one embodiment, the R₁, R₂ and R₃ radicals have naphthalene groups. In one embodiment, the R₁, R₂ and/or R₃ radicals have alkaryl groups. The alkyl groups here preferably have 1 to 10 carbon atoms. By way of example, the compound of the formula (6) is shown below. In a preferred embodiment, the TP compound has two or more triphenylene structural units. Corresponding compounds are shown by way of example in the formulae (7) to (13) and (16). In a preferred embodiment, the TP compound consists of triphenylene structural elements. In a particular embodiment, the triphenylene compound has at least one fused benzene radical bonded to the triphenylene group via one edge of the ring. Such compounds contain a chrysene structural element or a higher structural element such as picene. Such compounds are shown by way of example in the formulae (14) and (15).

In a preferred embodiment, the TP compound is a compound of the abovementioned formula (2) having a central azatriphenylene group. In a preferred embodiment, this TP compound has only a single R₁, R₂ and R₃ substituent in total. The R₁, R₂ or R₃ radical may be an aryl or heteroaryl radical or an aromatic ring system having several aryl or heteroaryl groups bonded via single bonds. The R₁, R₂ or R₃ radical may be substituted in the a position to the N of the azatriphenylene group. Such compounds are disclosed, for example, in WO 2010/132524 A1. Corresponding compounds are shown by way of example in the formulae (39) to (58).

In a further preferred embodiment, the TP compound has at least one structural unit selected from benzofuran, benzothiophene, benzoselenophene, dibenzofuran, dibenzothiophene and dibenzoselenophene. The compounds mentioned may have further aromatic rings fused to one of the groups mentioned. The structural unit may consist, for example, of four fused rings. Such compounds are described in WO 2011/137157 A1. Corresponding compounds are shown in the formulae (59) to (68) below. In one embodiment, none of the R₁, R₂ or R₃ radicals has five fused rings.

In a further preferred embodiment, a TP compound of the formula (1) has a plurality of, especially four, identical R₁ substituents. In this case, R₁ is especially a phenyl radical bonded to the central triphenylene via a C—C single bond. The compound preferably additionally has one R₂ substituent and one R₃ substituent, which are preferably identical to one another. The R₂ and R₃ substituents may, for example, be aryl or heteroaryl groups. Such compounds are disclosed in WO 2009/037155 A1. Corresponding compounds are shown by way of example in the formulae (69) to (71) below.

In a further, particularly preferred embodiment, the compound of the formula (1) has a structural element which is a carbazole group, azacarbazole group or diazacarbazole group. In a preferred embodiment, exclusively R₁, R₂ and R₃ radicals having a carbazole group, azacarbazole group or diazacarbazole group are present. In this case, preferably only one or two of these substituents are present. The R₁, R₂ or R₃ radical may consist of the carbazole group, azacarbazole group or diazacarbazole group. Preferably, the radical is bonded to the triphenylene group via the nitrogen atom of the 5-membered ring. Corresponding compounds are disclosed in JP 2006/143845. Corresponding compounds are shown by way of example in the formulae (72) to (81) below.

In a further preferred embodiment of the invention, the TP compound has at least two, especially exactly two, triphenylene groups bonded via a heteroaryl group or an aromatic ring system having a heteroaryl group. In this case, the triphenylene groups are bonded to the heteroaryl groups or the aromatic ring system preferably via single bonds. The heteroaryl group may especially be an N-containing heteroaryl group, especially an azine such as pyridine, pyrimidine or triazine, or a carbazole. Such compounds are disclosed in KR 2011/0041729. Corresponding compounds are shown by way of example in the formulae (82) to (91) below.

In a further preferred embodiment, the TP compound has a single triphenylene structural unit substituted by a single radical. This radical has an aromatic structural unit containing at least one nonfused aryl group, especially a benzene group, and at least one nonfused N-containing heteroaryl group, especially carbazole or indole. Preferably, this aromatic ring system has four to eight rings. An aryl group may be substituted by a halogen atom. Such compounds are disclosed in WO 2011/081423. Corresponding compounds are shown by way of example by the formulae (92) to (100),

In a further preferred embodiment, the TP compound has a single triphenylene group substituted by at least one radical which is anthracene in which at least one CH is replaced by a heteroatom. More particularly, the structural element is a dithiaanthracene or thiaoxaanthracene. More preferably, the structural element is a 9,10-dithiaanthracene or 9-oxa-10-thiaanthracene. Corresponding compounds are disclosed in WO 2011/081451 A1. Corresponding compounds are shown by way of example in the formulae (101) to (108). The compounds preferably have only a single R₁, R₂ or R₂ substituent in total. The compound may have a halogen substituent.

In a preferred embodiment of the invention, one of the R₁, R₂ or R₃ radicals has a carbazole group having at least one further fused ring. The carbazole group thus has at least four rings. It is preferable here that the carbazole group has five rings each joined via one side of the ring, the carbazole group being bonded to an outer aromatic ring via a fourth ring which is nonaromatic. Preferably, such a TP compound has only a single R₁, R₂ or R₃ substituent in total. Preferably, this compound has a single triphenylene group bonded to the carbazole group via a single bond. The bond may be to the nitrogen atom of the carbazole group. Such compounds and the preparation thereof are described in WO 2013/056776. Corresponding compounds are shown by way of example in the formulae (121) to (154) below. Alternatively, the compound may have a single triphenylene group bonded to the carbazole group via an aromatic ring structure. It is possible here for one or more aryl or heteroaryl radicals, for example a benzyl group or biphenyl group, to be positioned between the triphenylene group and the carbazole group. Preferably, such a TP compound has only a single R₁, R₂ or R₃ substituent in total. Such compounds and the preparation thereof are described in WO 2012/039561 A1. Corresponding compounds are shown by way of example in the formulae (109) to (120) below.

In preferred embodiments of the invention, the TP compound is a compound of the following formulae (3a) to (154):

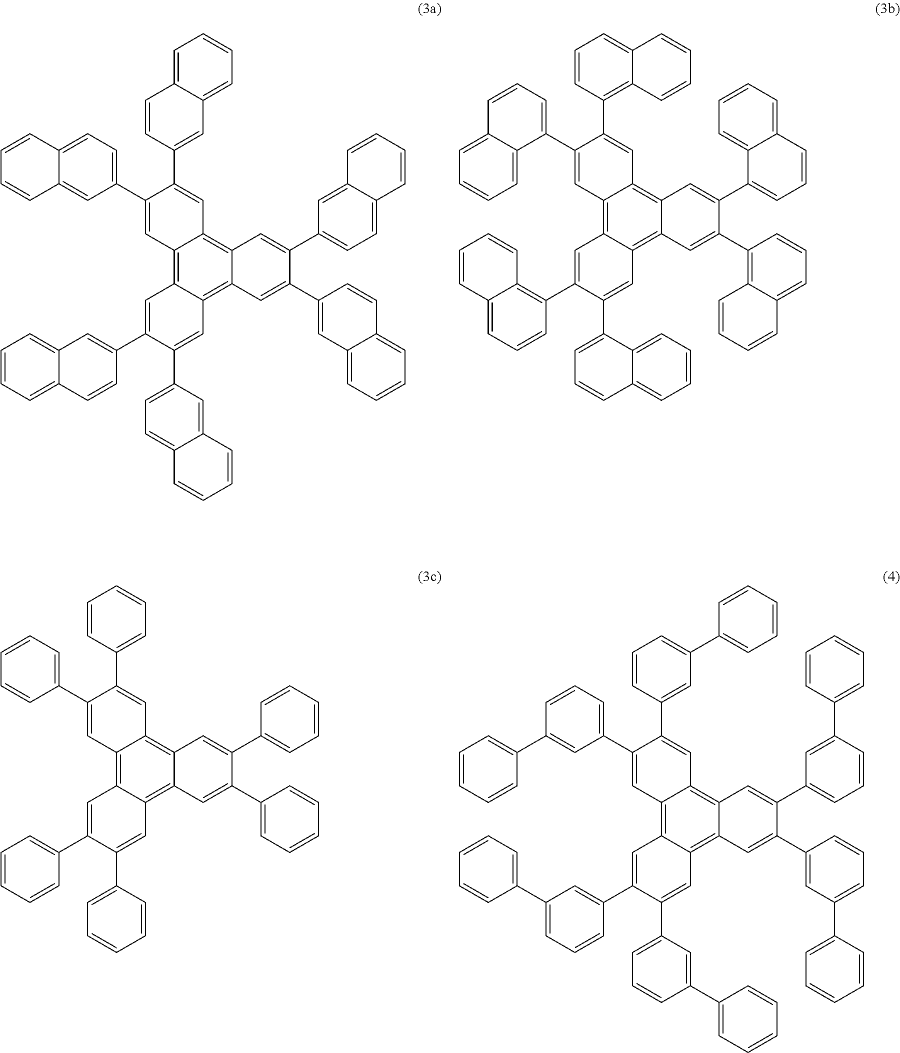

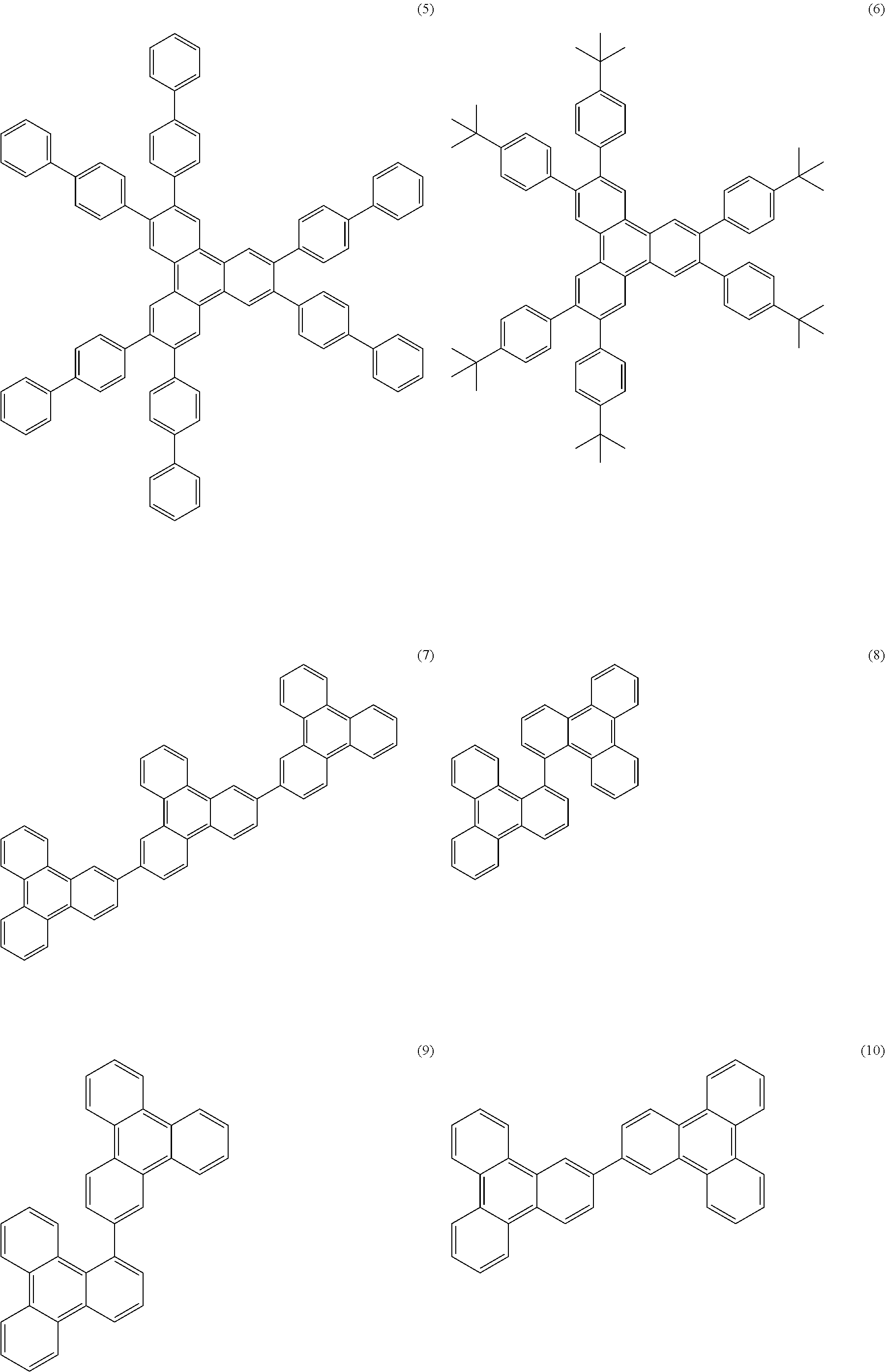

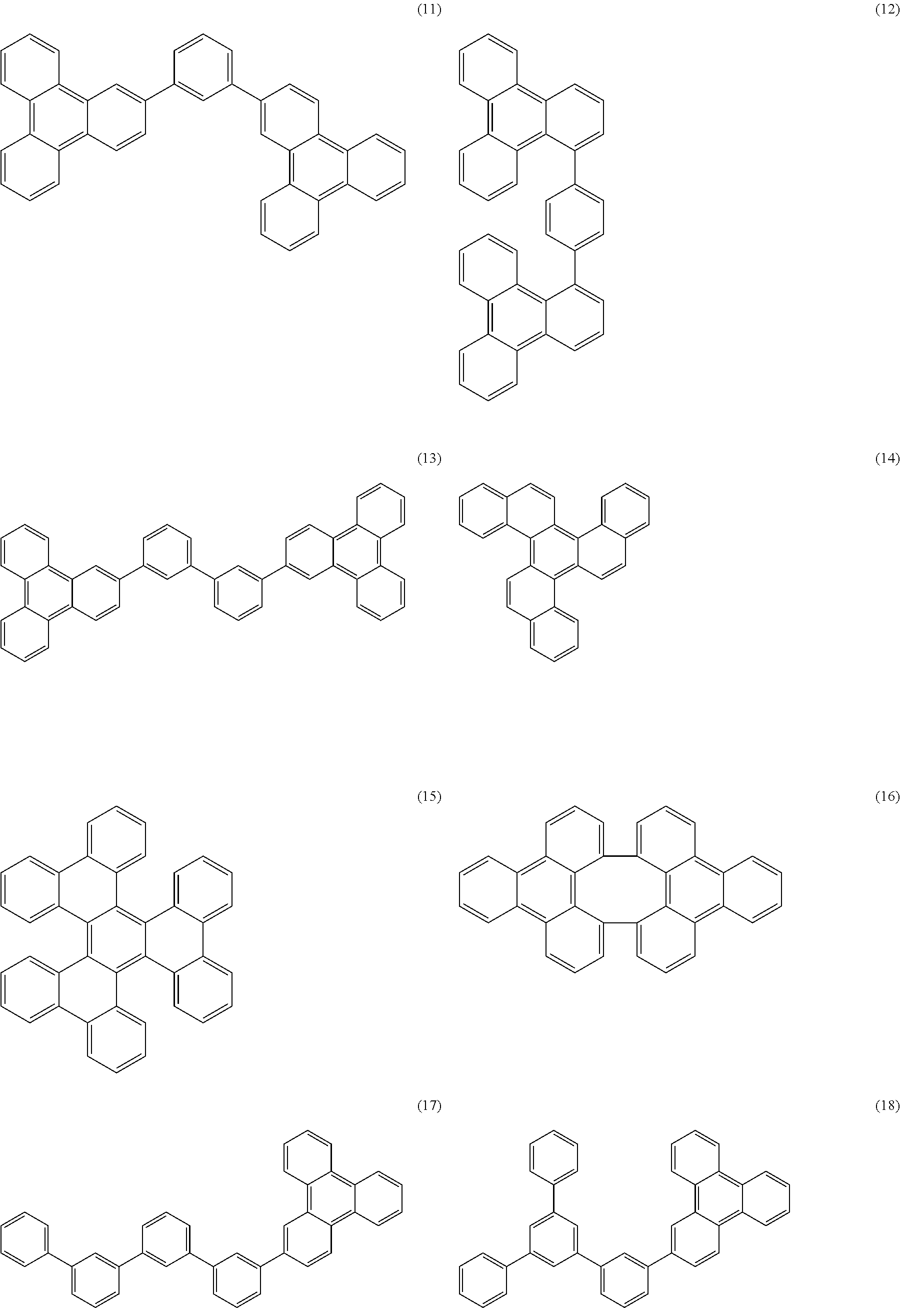

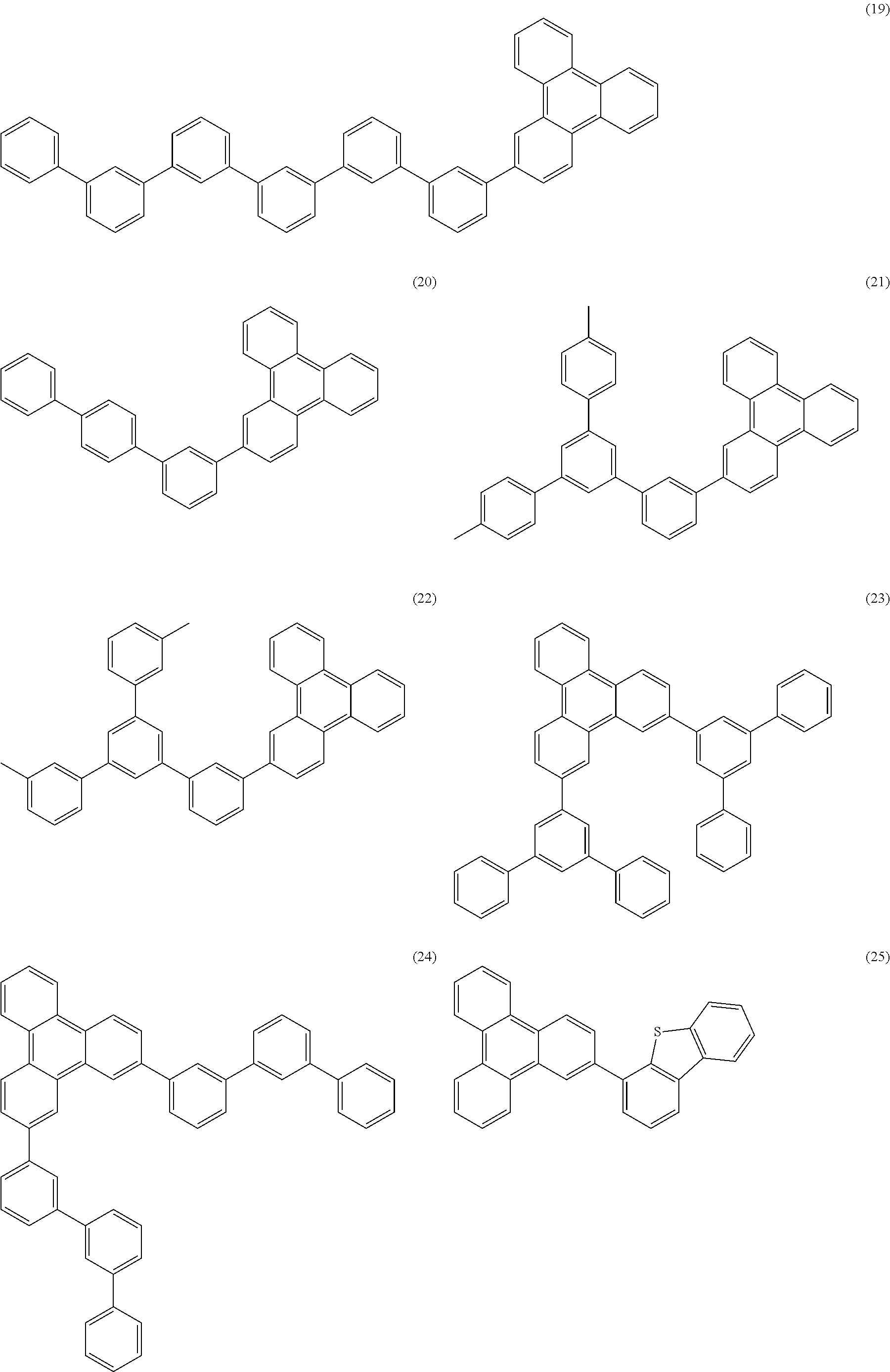

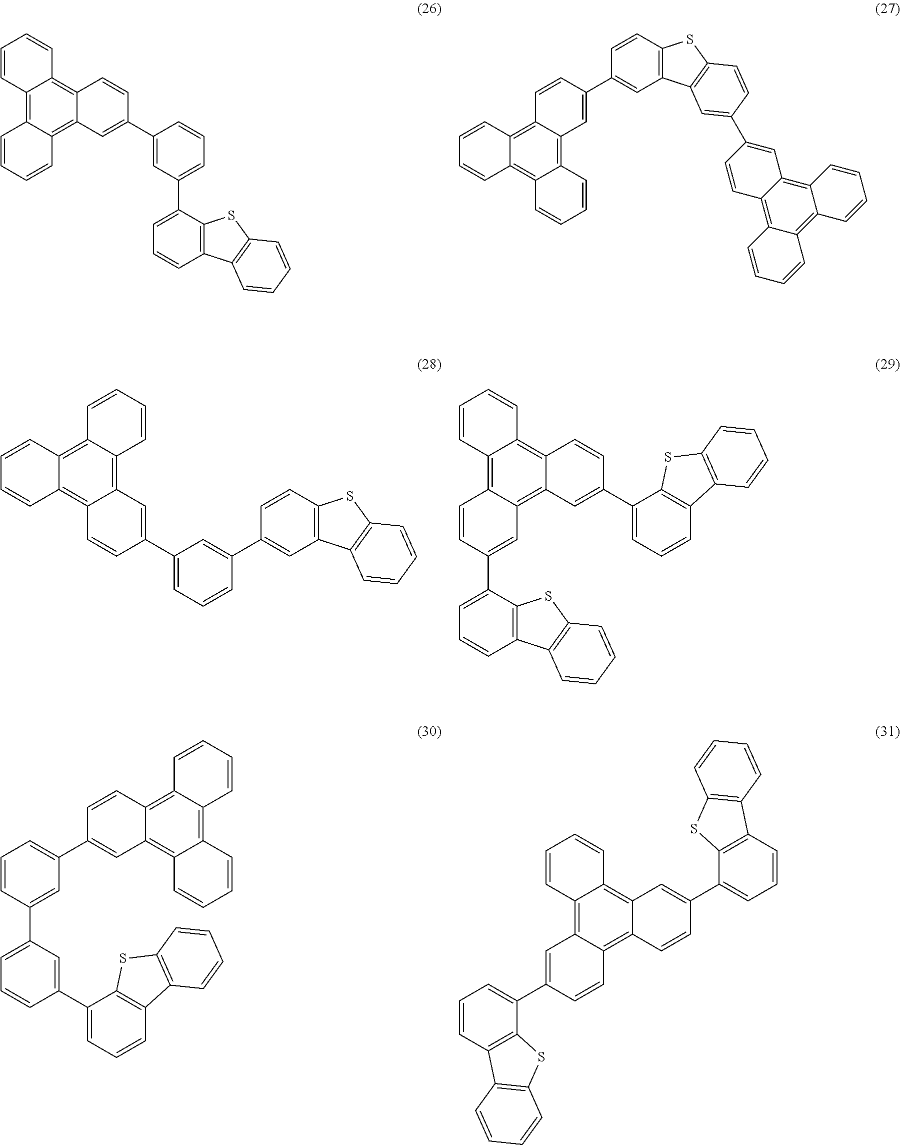

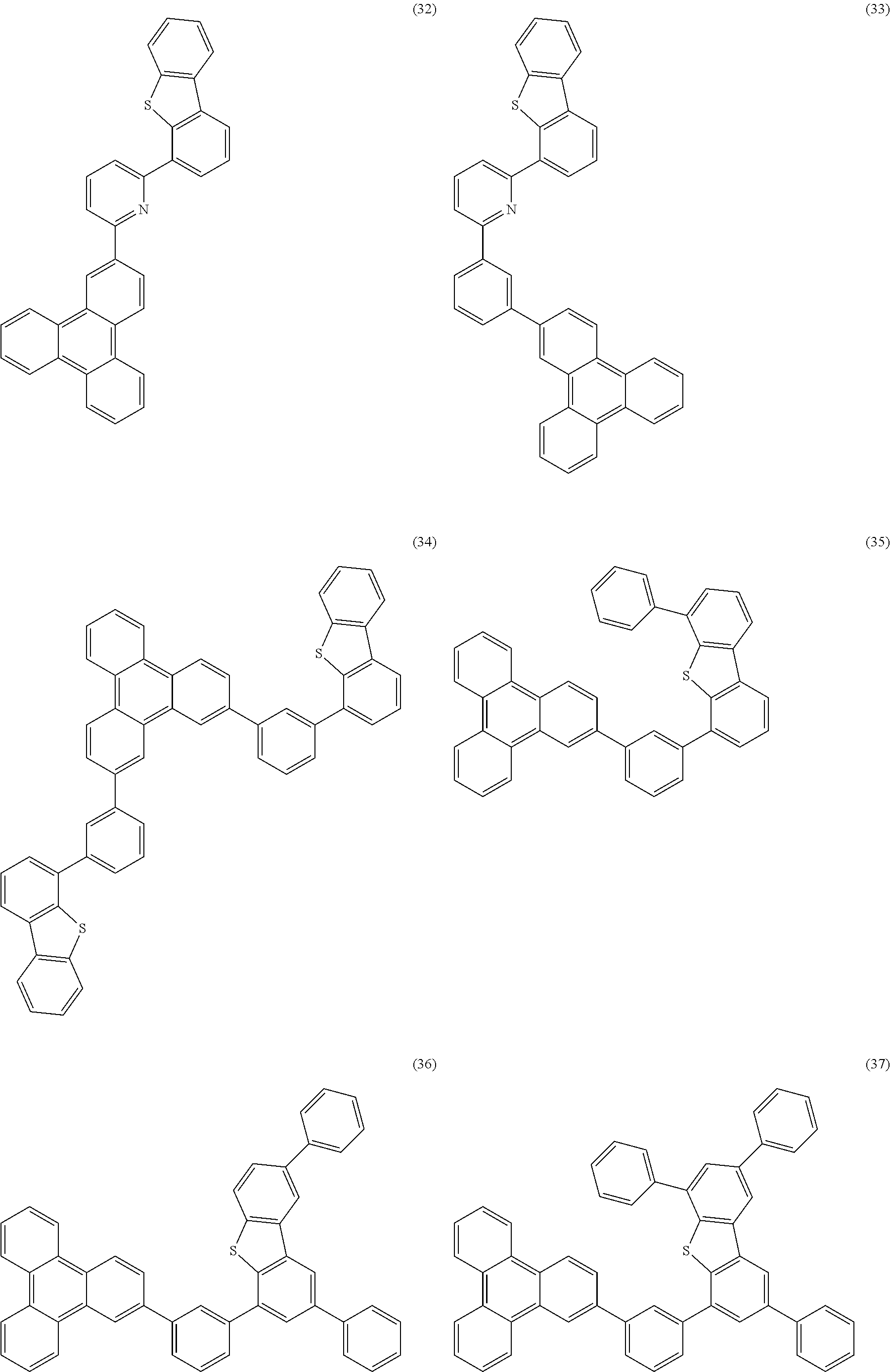 [SMILES: c1cc(-c2ccc3c4ccccc4c4ccccc4c3c2)nc(-c2cccc3c2sc2ccccc23)c1 ; c1cc(-c2ccc3c4ccccc4c4ccccc4c3c2)cc(-c2cccc(-c3cccc4c3sc3ccccc34)n2)c1 ; c1cc(-c2ccc3c4ccccc4c4ccc(-c5cccc(-c6cccc7c6sc6ccccc67)c5)cc4c3c2)cc(-c2cccc3c2sc2ccccc23)c1 ; c1ccc(-c2cccc3c2sc2c(-c4cccc(-c5ccc6c7ccccc7c7ccccc7c6c5)c4)cccc23)cc1 ; c1ccc(-c2ccc3sc4c(-c5cccc(-c6ccc7c8ccccc8c8ccccc8c7c6)c5)cc(-c5ccccc5)cc4c3c2)cc1 ; c1ccc(-c2cc(-c3ccccc3)c3sc4c(-c5cccc(-c6ccc7c8ccccc8c8ccccc8c7c6)c5)cc(-c5ccccc5)cc4c3c2)cc1]

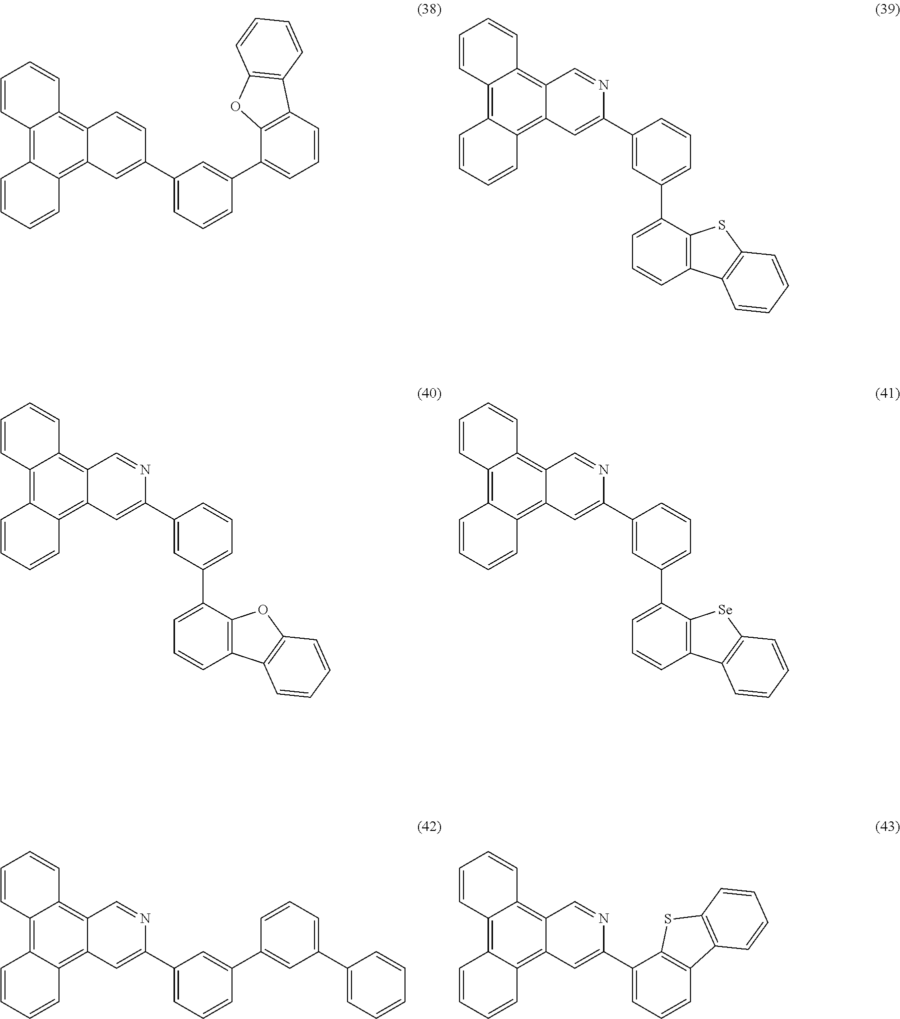 [SMILES: c1cc(-c2ccc3c4ccccc4c4ccccc4c3c2)cc(-c2cccc3c2oc2ccccc23)c1 ; c1cc(-c2cc3c4ccccc4c4ccccc4c3cn2)cc(-c2cccc3c2sc2ccccc23)c1 ; c1cc(-c2cc3c4ccccc4c4ccccc4c3cn2)cc(-c2cccc3c2oc2ccccc23)c1 ; c1cc(-c2cc3c4ccccc4c4ccccc4c3cn2)cc(-c2cccc3c2[se]c2ccccc23)c1 ; c1ccc(-c2cccc(-c3cccc(-c4cc5c6ccccc6c6ccccc6c5cn4)c3)c2)cc1 ; c1ccc2c(c1)sc1c(-c3cc4c5ccccc5c5ccccc5c4cn3)cccc12]

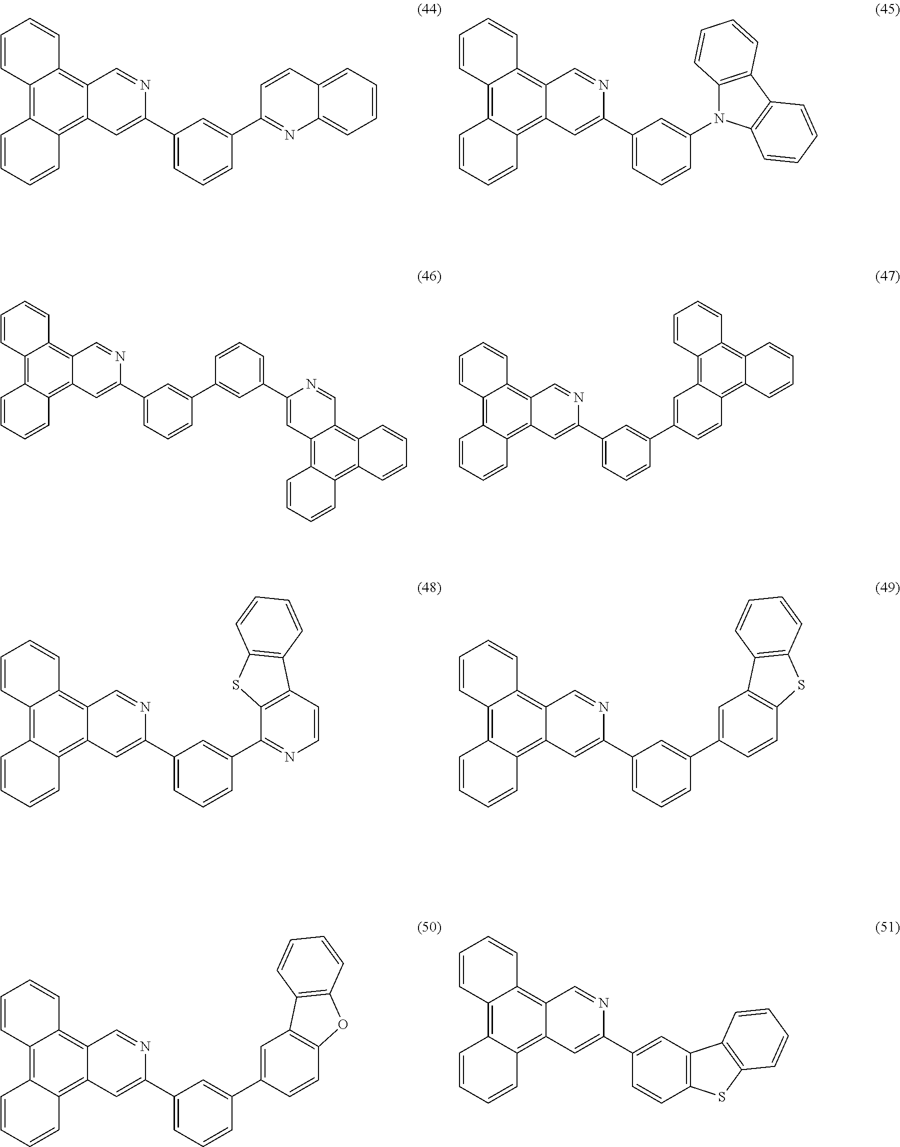

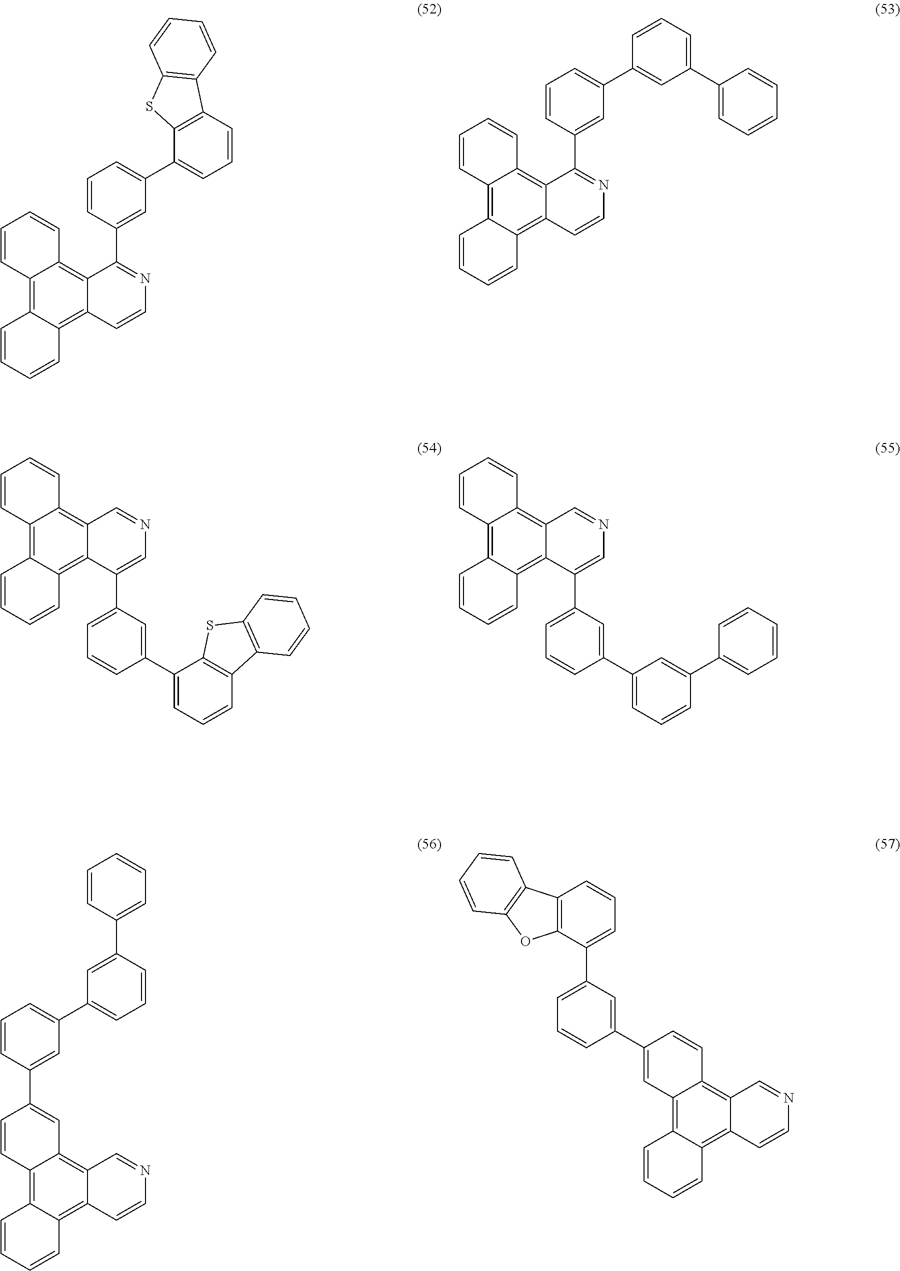 [SMILES: c1cc(-c2cccc3c2sc2ccccc23)cc(-c2nccc3c4ccccc4c4ccccc4c23)c1 ; c1ccc(-c2cccc(-c3cccc(-c4nccc5c6ccccc6c6ccccc6c45)c3)c2)cc1 ; c1cc(-c2cccc3c2sc2ccccc23)cc(-c2cncc3c4ccccc4c4ccccc4c23)c1 ; c1ccc(-c2cccc(-c3cccc(-c4cncc5c6ccccc6c6ccccc6c45)c3)c2)cc1 ; c1ccc(-c2cccc(-c3cccc(-c4ccc5c6ccccc6c6ccncc6c5c4)c3)c2)cc1 ; c1cc(-c2ccc3c4cnccc4c4ccccc4c3c2)cc(-c2cccc3c2oc2ccccc23)c1]

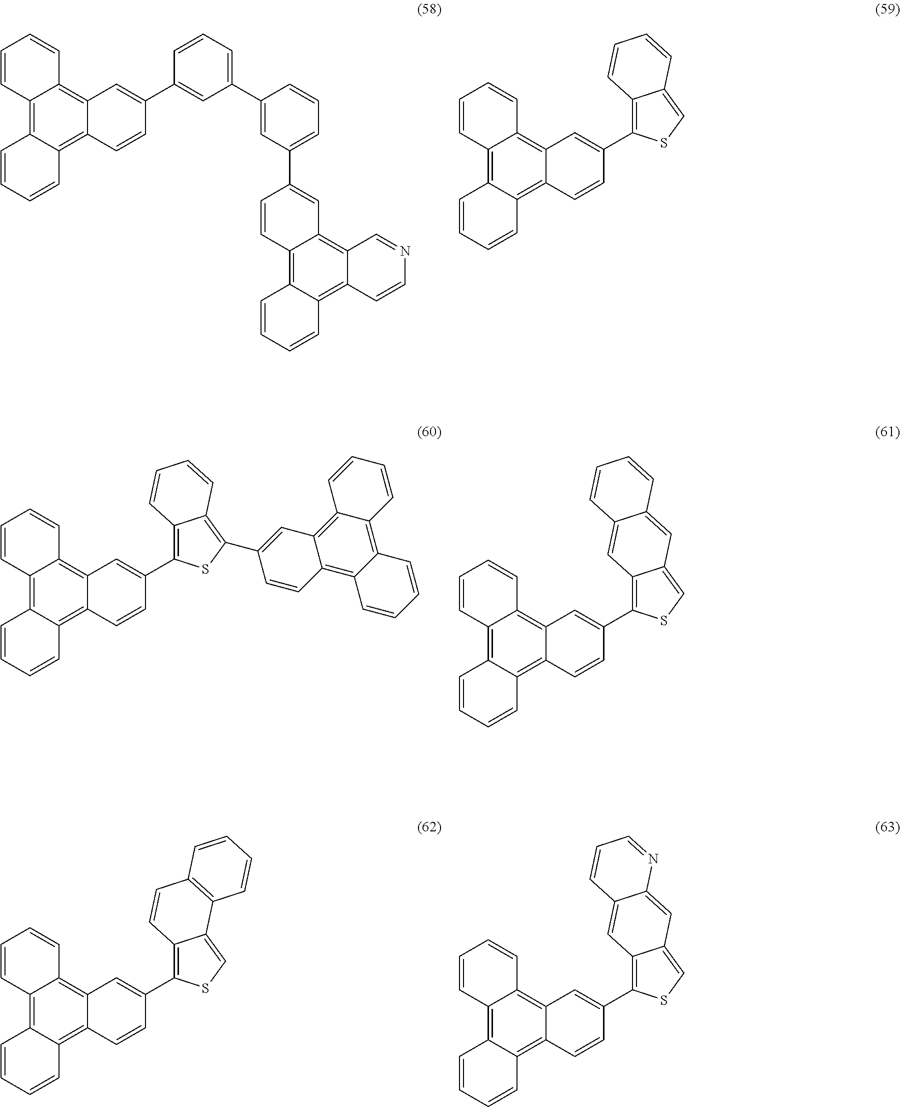

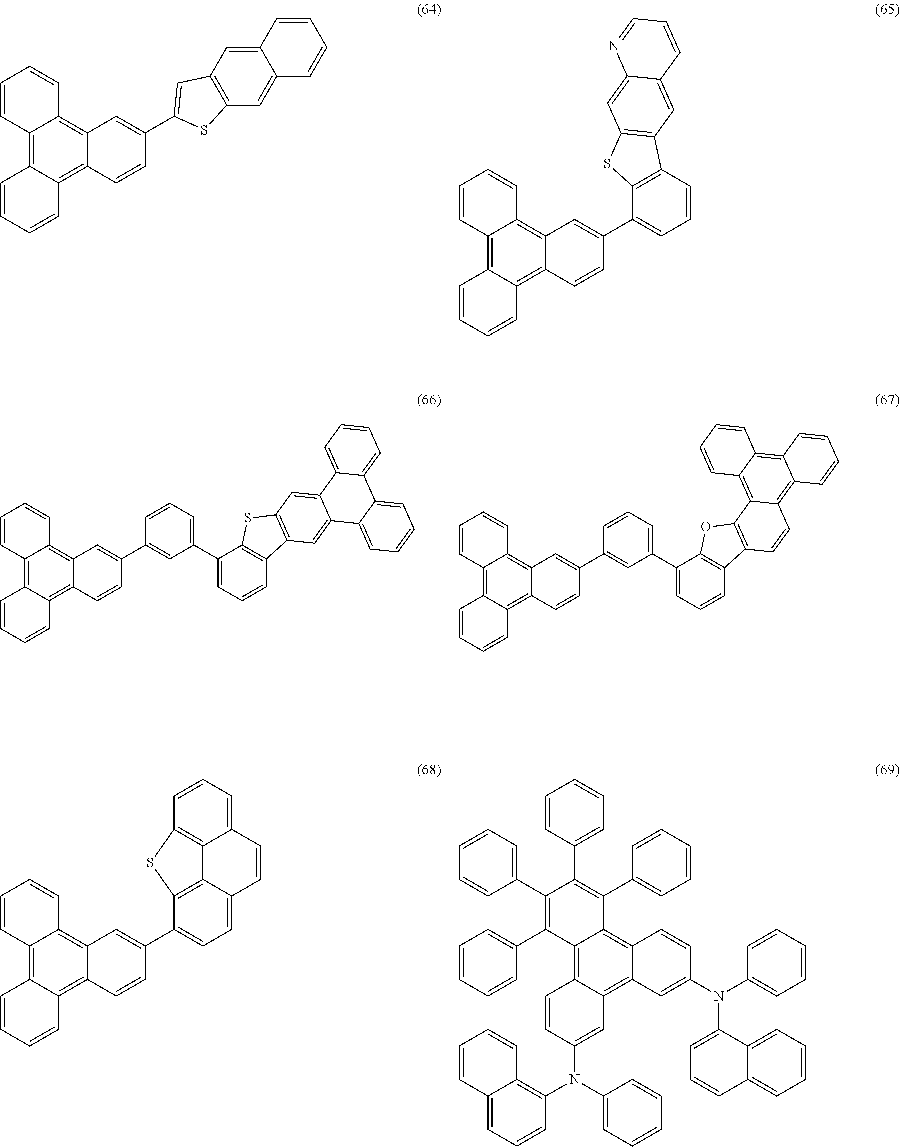

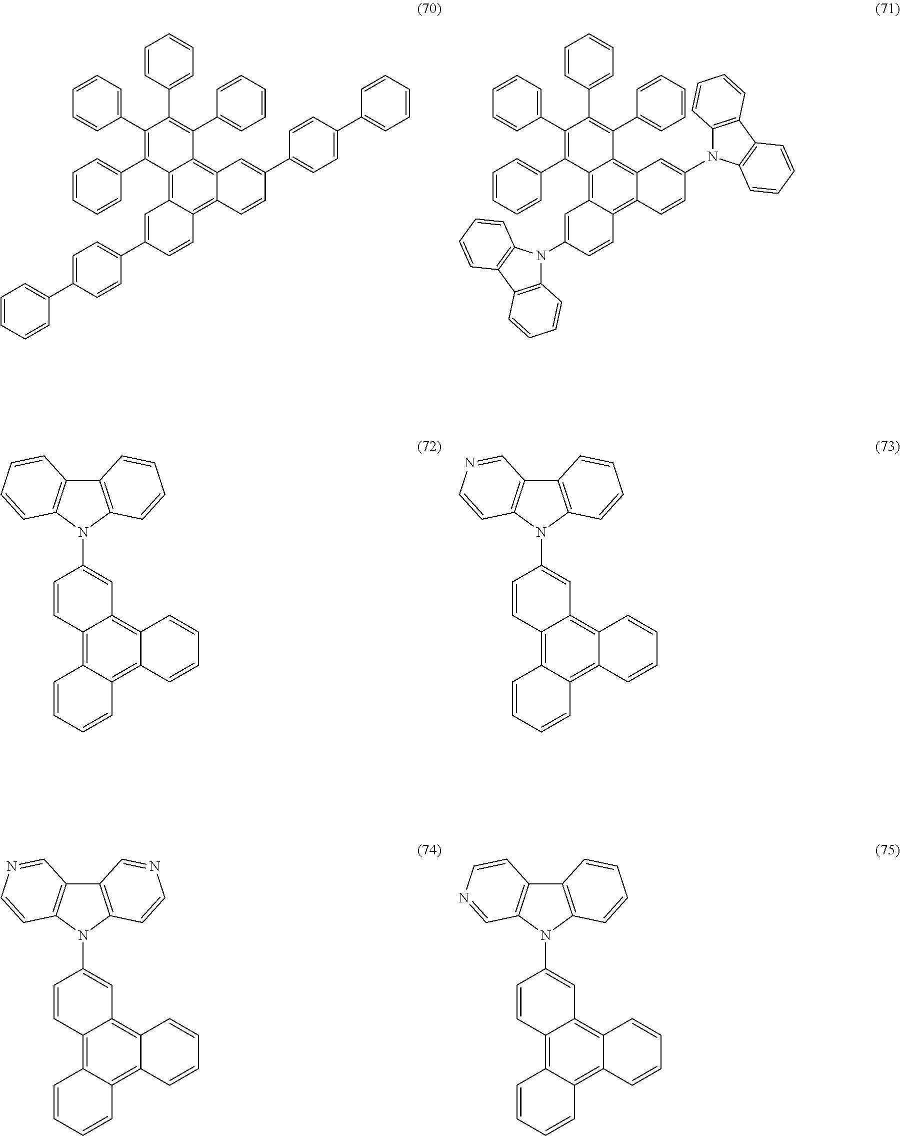

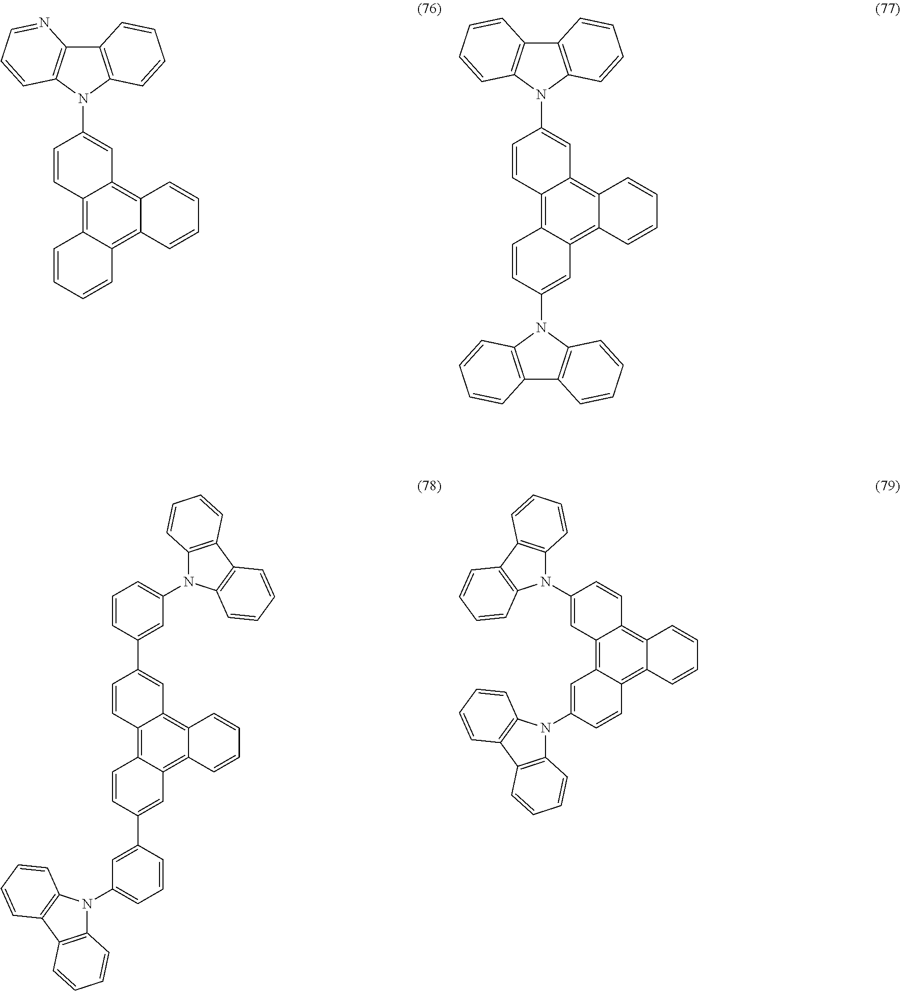 [SMILES: c1ccc2c(c1)c1ccccc1c1cc(-n3c4ccccc4c4ncccc43)ccc21 ; c1ccc2c(c1)c1cc(-n3c4ccccc4c4ccccc43)ccc1c1ccc(-n3c4ccccc4c4ccccc43)cc21 ; c1cc(-c2ccc3c4ccc(-c5cccc(-n6c7ccccc7c7ccccc76)c5)cc4c4ccccc4c3c2)cc(-n2c3ccccc3c3ccccc32)c1 ; c1ccc2c(c1)c1ccc(-n3c4ccccc4c4ccccc43)cc1c1cc(-n3c4ccccc4c4ccccc43)ccc21]

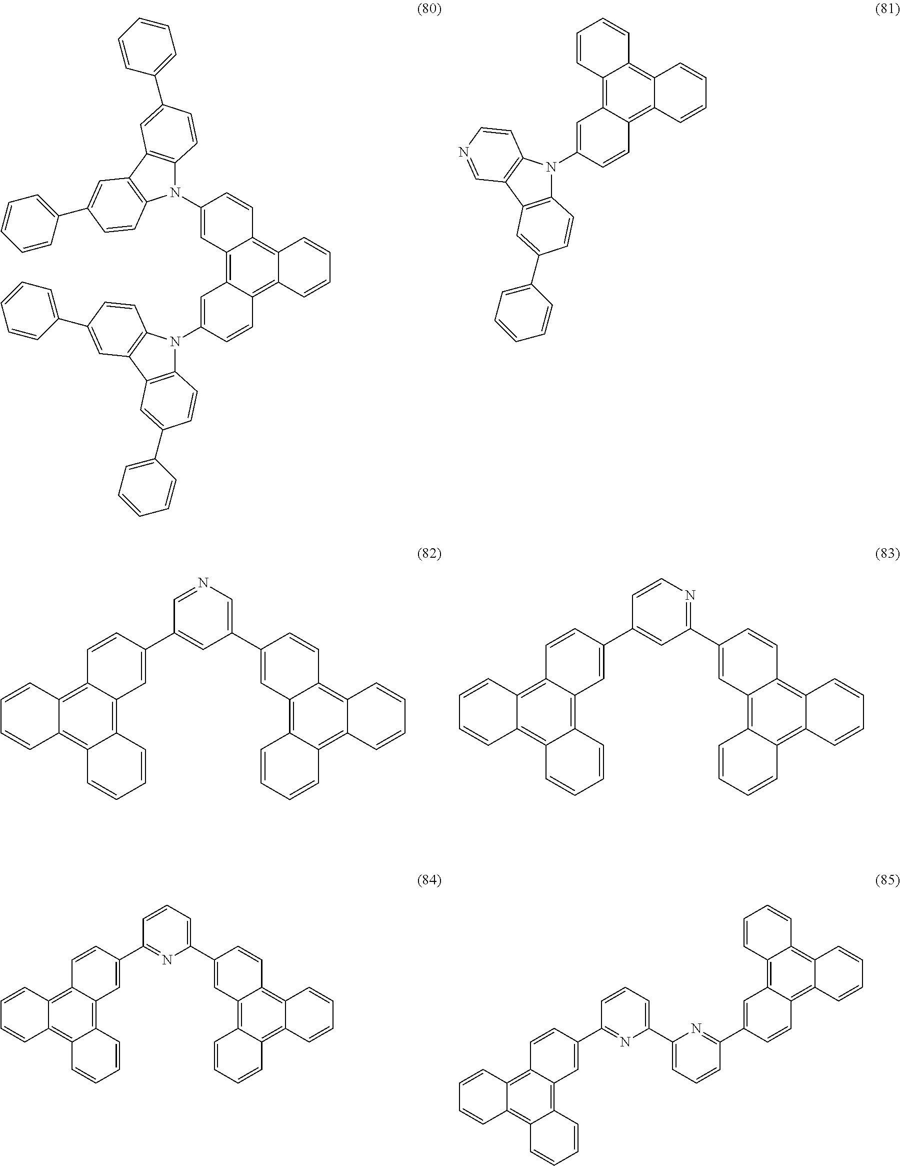 [SMILES: c1ccc(-c2ccc3c(c2)c2cc(-c4ccccc4)ccc2n3-c2ccc3c4ccccc4c4ccc(-n5c6ccc(-c7ccccc7)cc6c6cc(-c7ccccc7)ccc65)cc4c3c2)cc1 ; c1ccc(-c2ccc3c(c2)c2cnccc2n3-c2ccc3c4ccccc4c4ccccc4c3c2)cc1 ; c1ccc2c(c1)c1ccccc1c1cc(-c3cncc(-c4ccc5c6ccccc6c6ccccc6c5c4)c3)ccc21 ; c1ccc2c(c1)c1ccccc1c1cc(-c3ccnc(-c4ccc5c6ccccc6c6ccccc6c5c4)c3)ccc21 ; c1cc(-c2ccc3c4ccccc4c4ccccc4c3c2)nc(-c2ccc3c4ccccc4c4ccccc4c3c2)c1 ; c1cc(-c2ccc3c4ccccc4c4ccccc4c3c2)nc(-c2cccc(-c3ccc4c5ccccc5c5ccccc5c4c3)n2)c1]

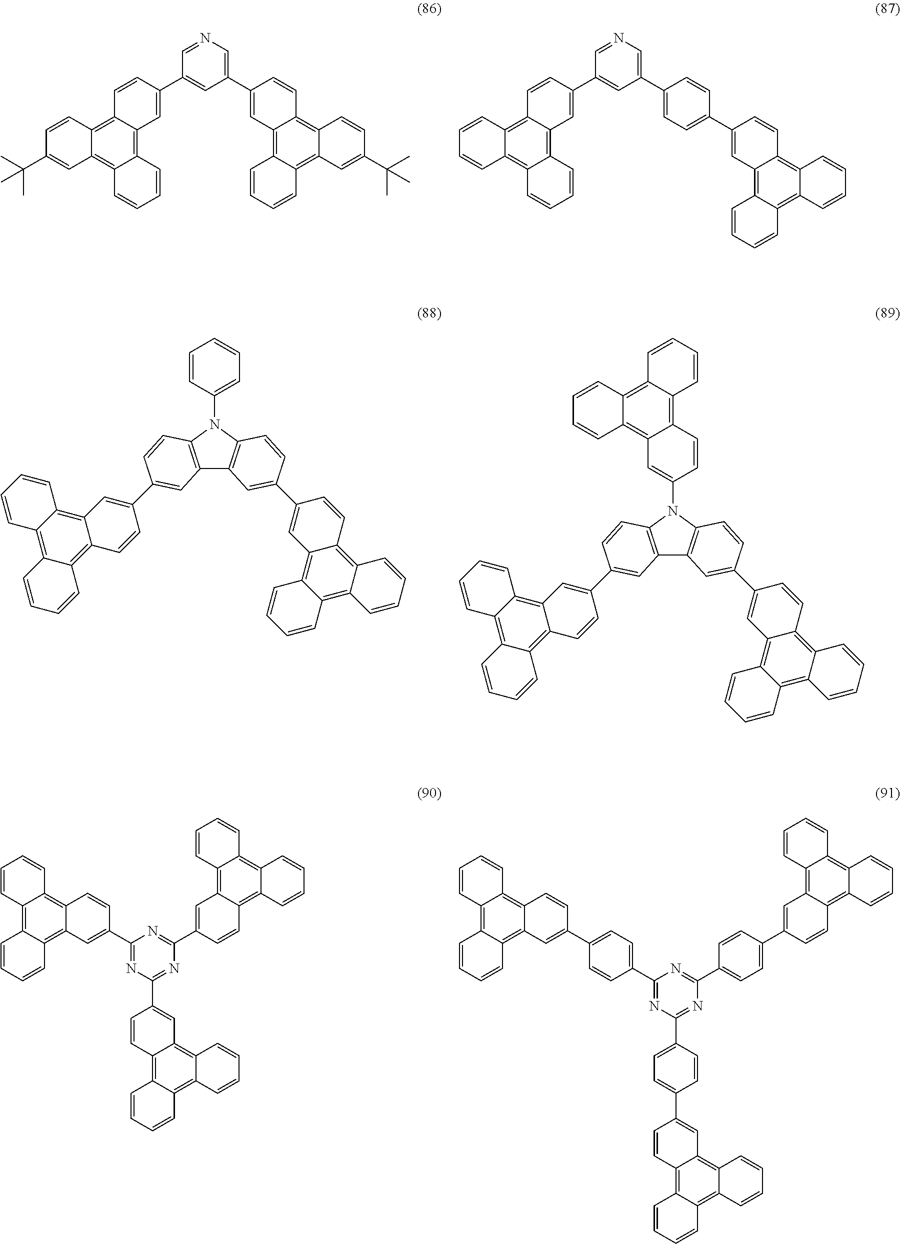

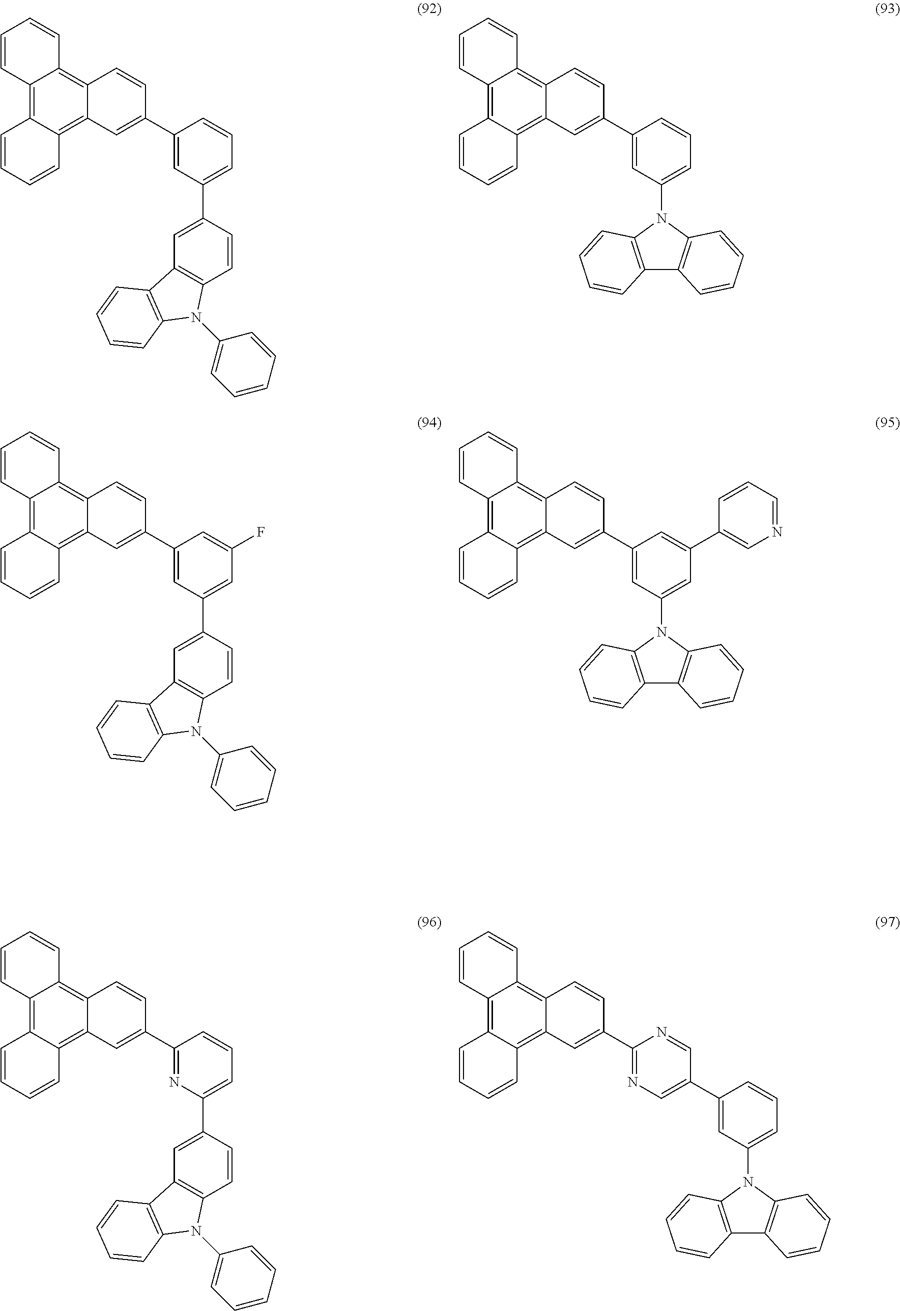 [SMILES: c1ccc(-n2c3ccccc3c3cc(-c4cccc(-c5ccc6c7ccccc7c7ccccc7c6c5)c4)ccc32)cc1 ; c1cc(-c2ccc3c4ccccc4c4ccccc4c3c2)cc(-n2c3ccccc3c3ccccc32)c1 ; Fc1cc(-c2ccc3c4ccccc4c4ccccc4c3c2)cc(-c2ccc3c(c2)c2ccccc2n3-c2ccccc2)c1 ; c1cncc(-c2cc(-c3ccc4c5ccccc5c5ccccc5c4c3)cc(-n3c4ccccc4c4ccccc43)c2)c1 ; c1ccc(-n2c3ccccc3c3cc(-c4cccc(-c5ccc6c7ccccc7c7ccccc7c6c5)n4)ccc32)cc1 ; c1cc(-c2cnc(-c3ccc4c5ccccc5c5ccccc5c4c3)nc2)cc(-n2c3ccccc3c3ccccc32)c1]

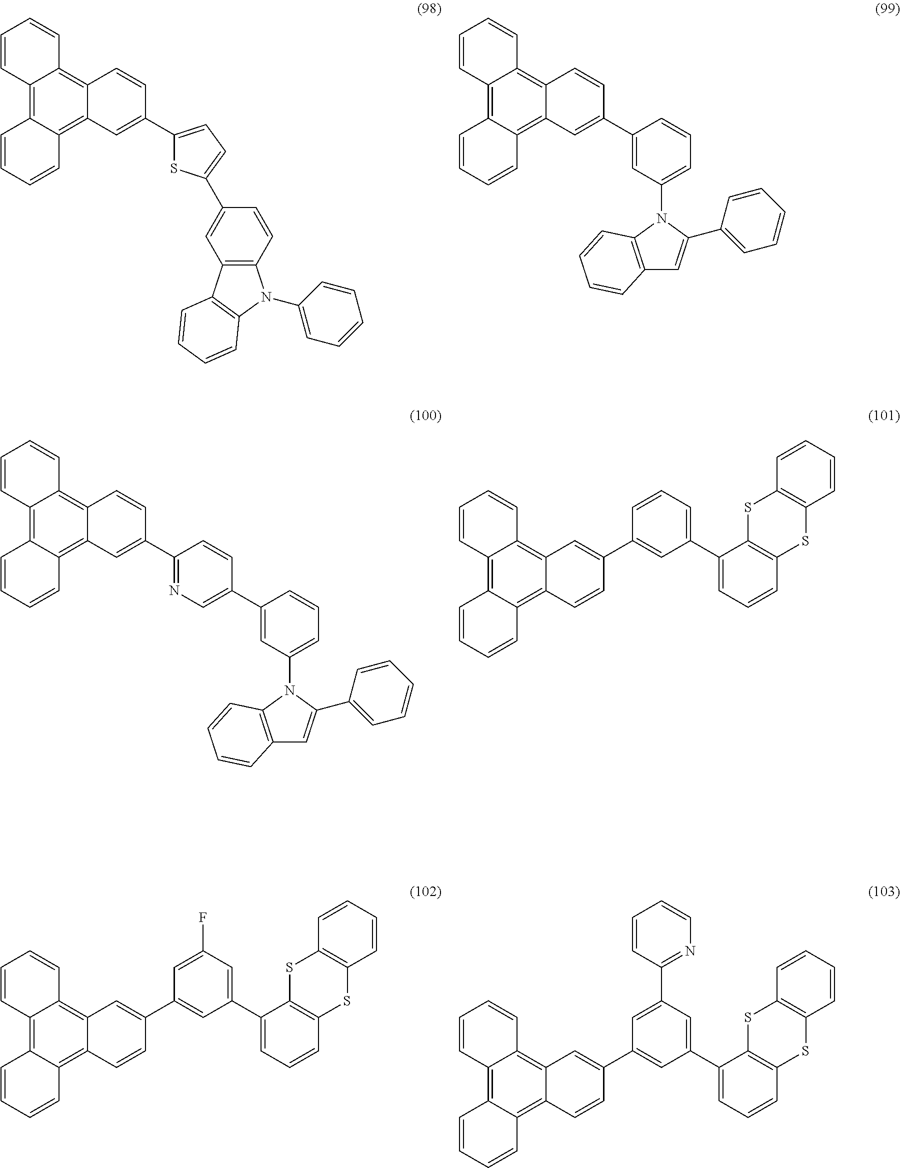 [SMILES: c1ccc(-n2c3ccccc3c3cc(-c4ccc(-c5ccc6c7ccccc7c7ccccc7c6c5)s4)ccc32)cc1 ; c1ccc(-c2cc3ccccc3n2-c2cccc(-c3ccc4c5ccccc5c5ccccc5c4c3)c2)cc1 ; c1ccc(-c2cc3ccccc3n2-c2cccc(-c3ccc(-c4ccc5c6ccccc6c6ccccc6c5c4)nc3)c2)cc1 ; c1cc(-c2ccc3c4ccccc4c4ccccc4c3c2)cc(-c2cccc3c2Sc2ccccc2S3)c1 ; Fc1cc(-c2ccc3c4ccccc4c4ccccc4c3c2)cc(-c2cccc3c2Sc2ccccc2S3)c1 ; c1ccc(-c2cc(-c3ccc4c5ccccc5c5ccccc5c4c3)cc(-c3cccc4c3Sc3ccccc3S4)c2)nc1]

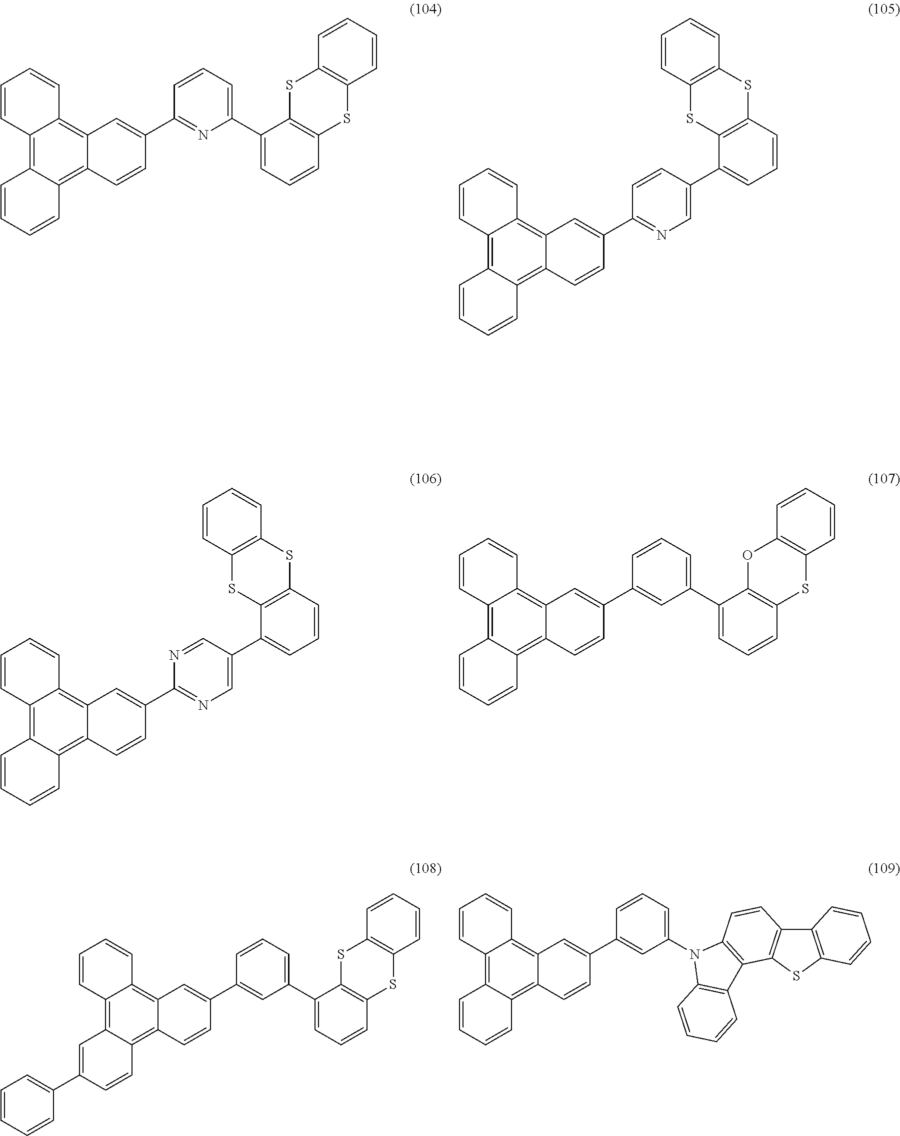

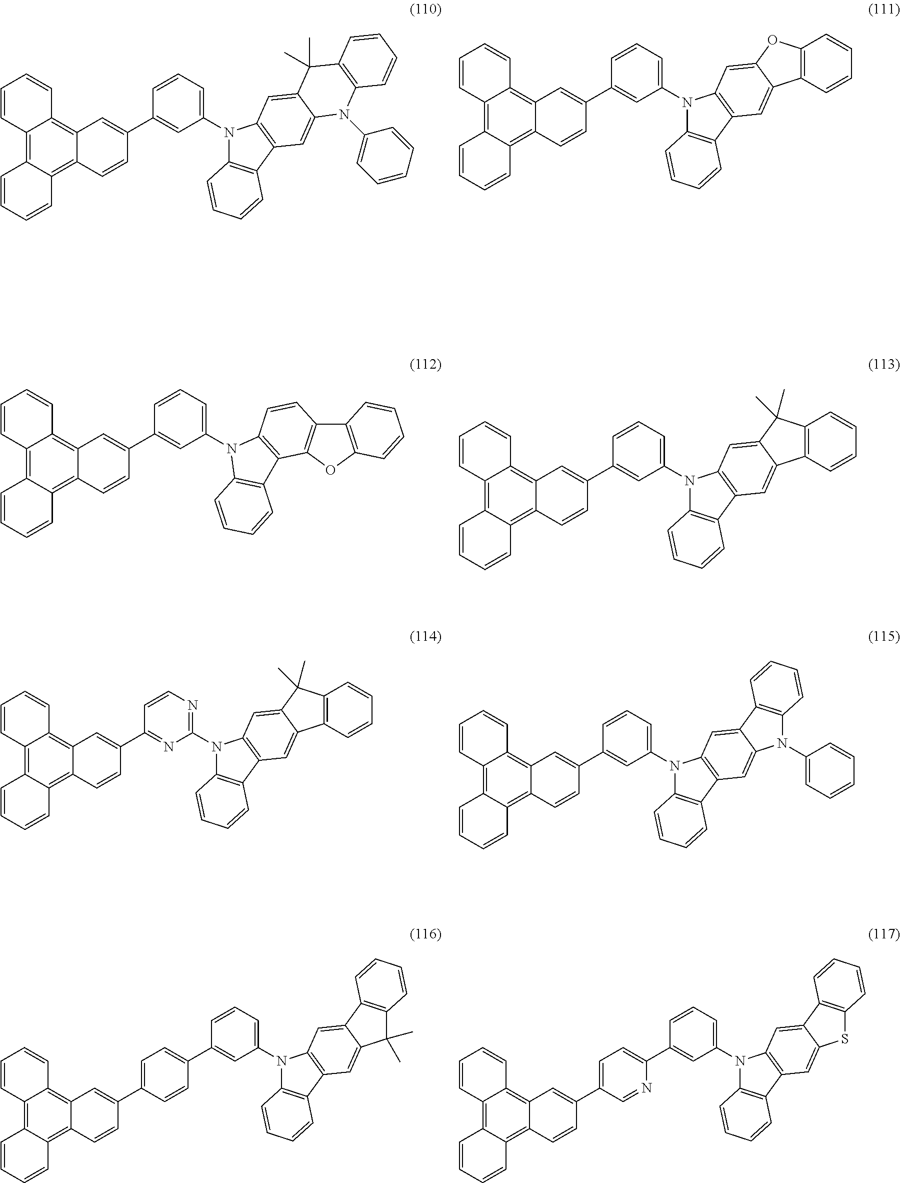

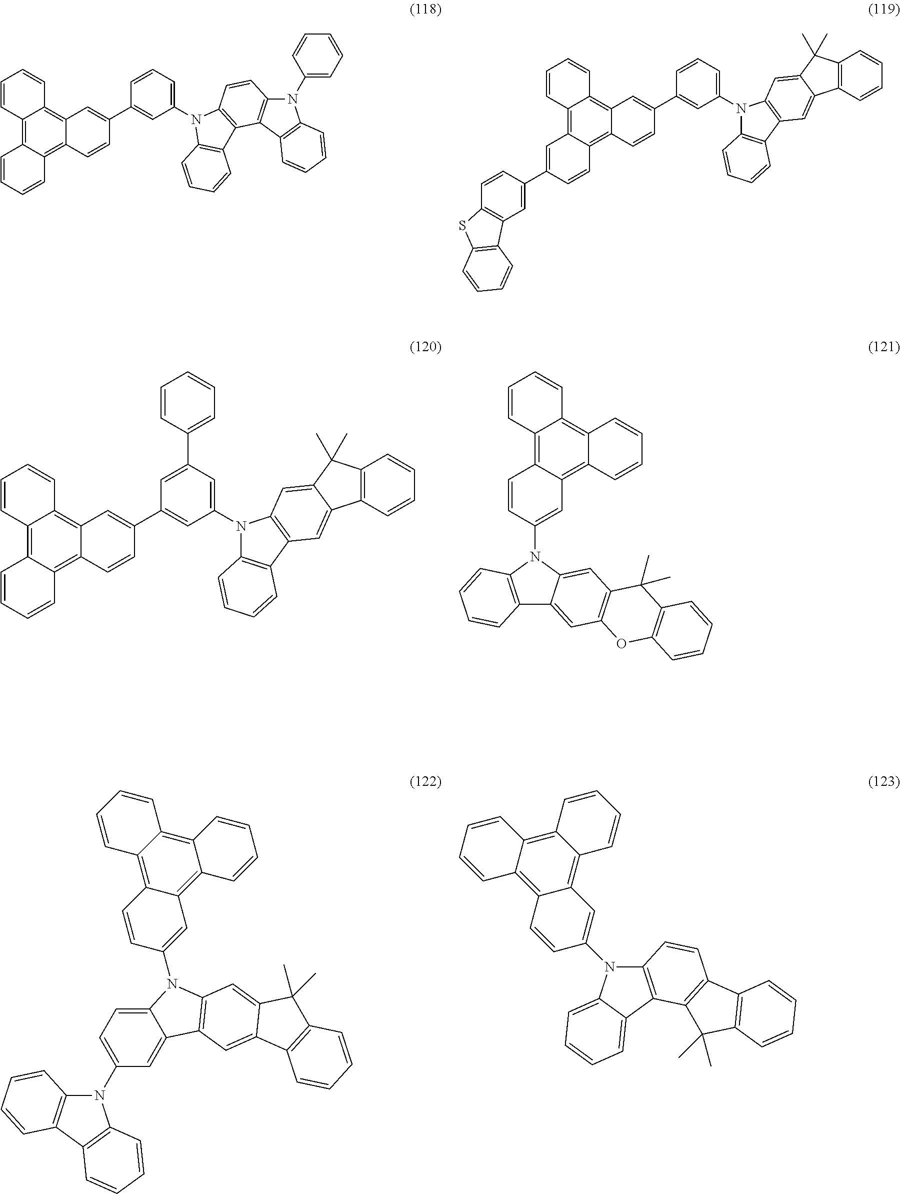 [SMILES: c1ccc(-n2c3ccccc3c3c4c5ccccc5n(-c5cccc(-c6ccc7c8ccccc8c8ccccc8c7c6)c5)c4ccc32)cc1 ; CC1(C)c2ccccc2-c2cc3c4ccccc4n(-c4cccc(-c5ccc6c7ccc(-c8ccc9sc%10ccccc%10c9c8)cc7c7ccccc7c6c5)c4)c3cc21 ; CC1(C)c2ccccc2-c2cc3c4ccccc4n(-c4cc(-c5ccccc5)cc(-c5ccc6c7ccccc7c7ccccc7c6c5)c4)c3cc21 ; CC1(C)c2ccccc2Oc2cc3c4ccccc4n(-c4ccc5c6ccccc6c6ccccc6c5c4)c3cc21 ; CC1(C)c2ccccc2-c2cc3c4cc(-n5c6ccccc6c6ccccc65)ccc4n(-c4ccc5c6ccccc6c6ccccc6c5c4)c3cc21 ; CC1(C)c2ccccc2-c2ccc3c(c21)c1ccccc1n3-c1ccc2c3ccccc3c3ccccc3c2c1]

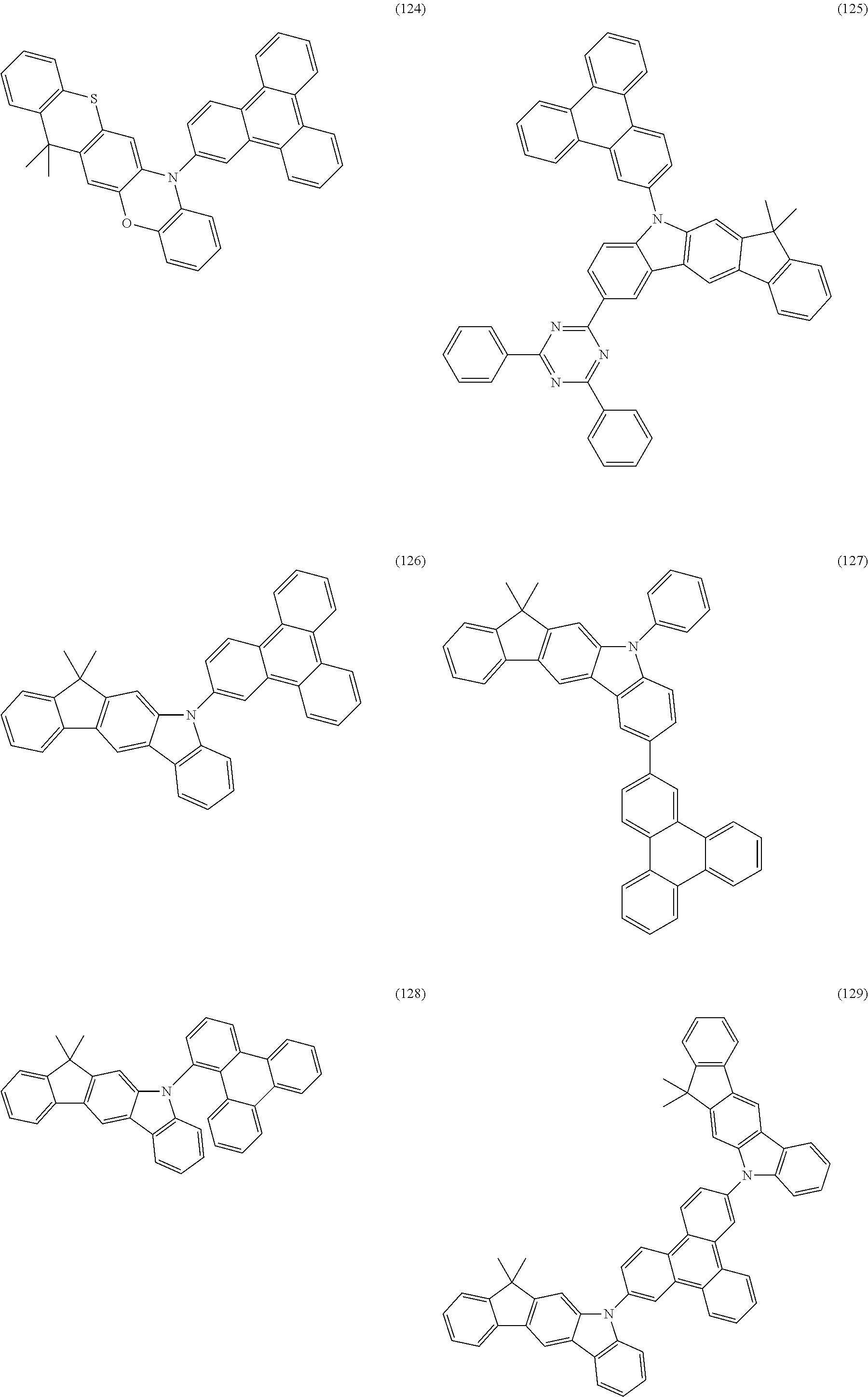 [SMILES: CC1(C)c2ccccc2Sc2cc3c(cc21)Oc1ccccc1N3c1ccc2c3ccccc3c3ccccc3c2c1 ; CC1(C)c2ccccc2-c2cc3c4cc(-c5nc(-c6ccccc6)nc(-c6ccccc6)n5)ccc4n(-c4ccc5c6ccccc6c6ccccc6c5c4)c3cc21 ; CC1(C)c2ccccc2-c2cc3c4ccccc4n(-c4ccc5c6ccccc6c6ccccc6c5c4)c3cc21 ; CC1(C)c2ccccc2-c2cc3c4cc(-c5ccc6c7ccccc7c7ccccc7c6c5)ccc4n(-c4ccccc4)c3cc21 ; CC1(C)c2ccccc2-c2cc3c4ccccc4n(-c4cccc5c6ccccc6c6ccccc6c45)c3cc21 ; CC1(C)c2ccccc2-c2cc3c4ccccc4n(-c4ccc5c6ccc(-n7c8ccccc8c8cc9c(cc87)C(C)(C)c7ccccc7-9)cc6c6ccccc6c5c4)c3cc21]

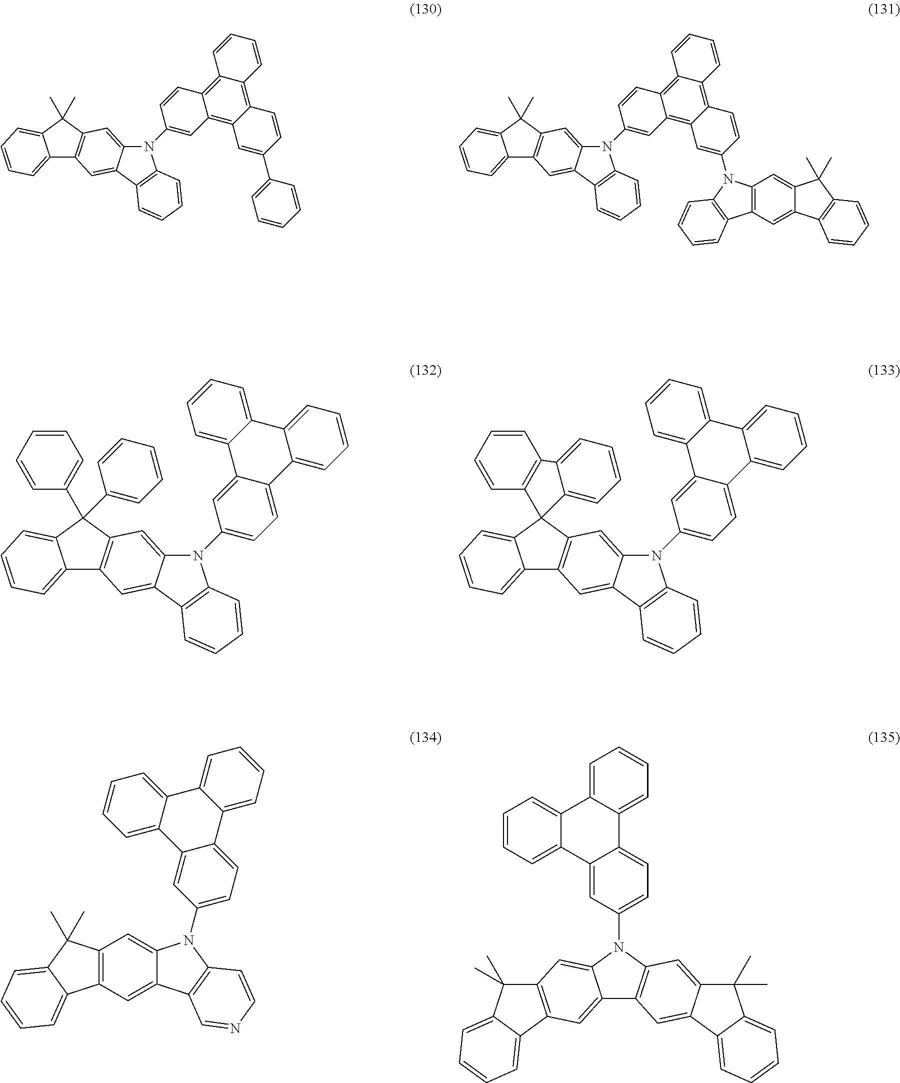

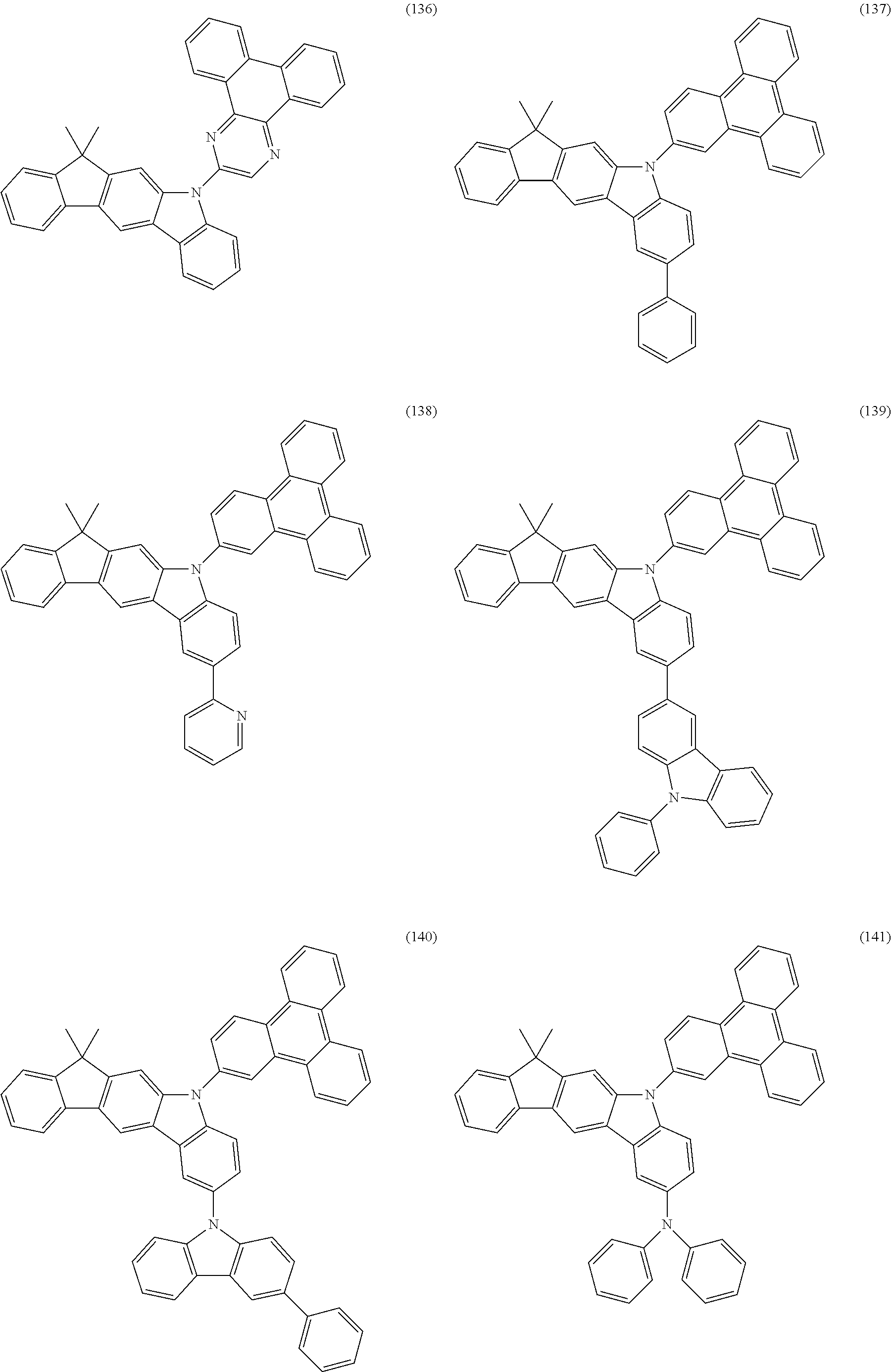

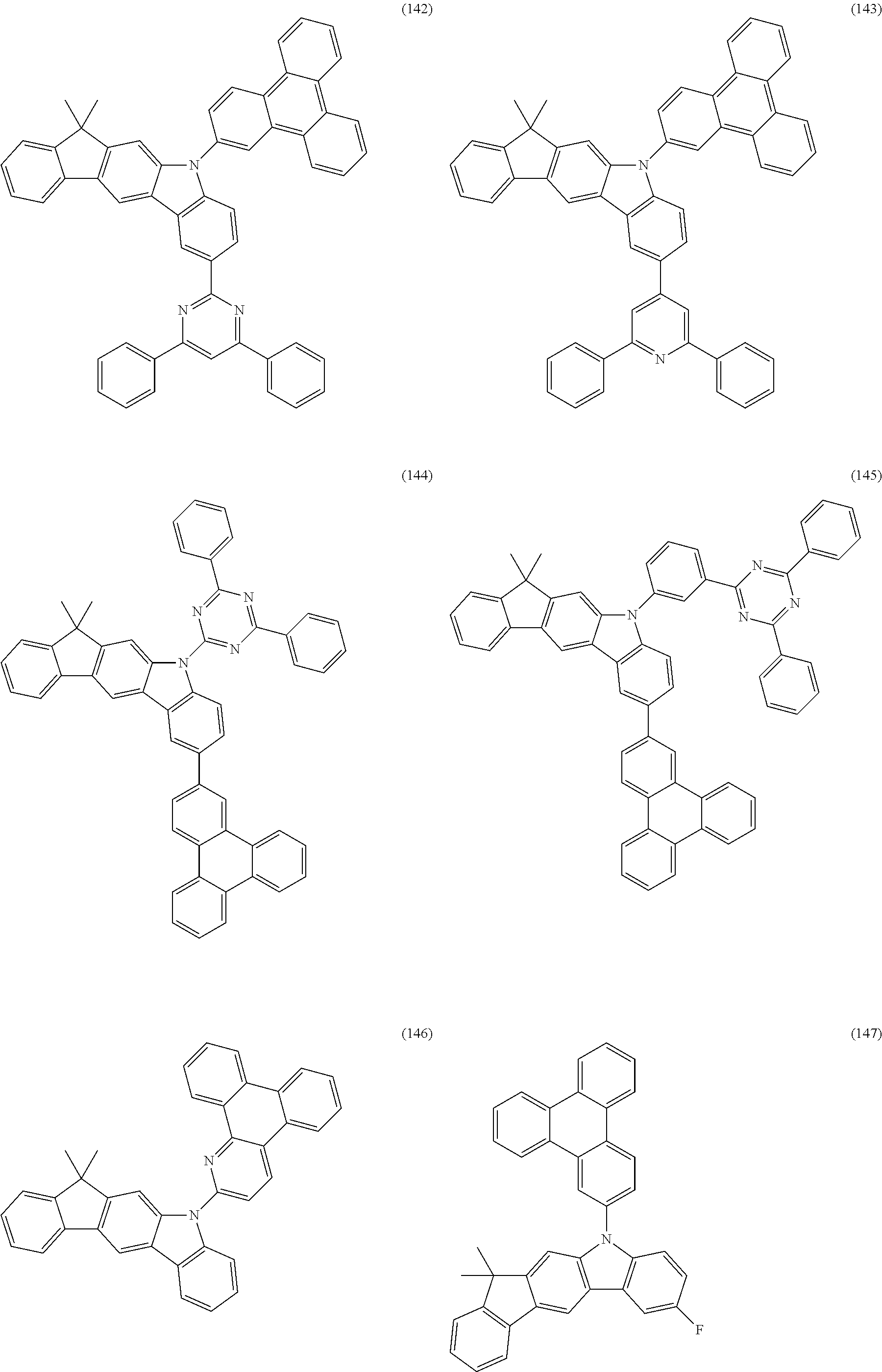

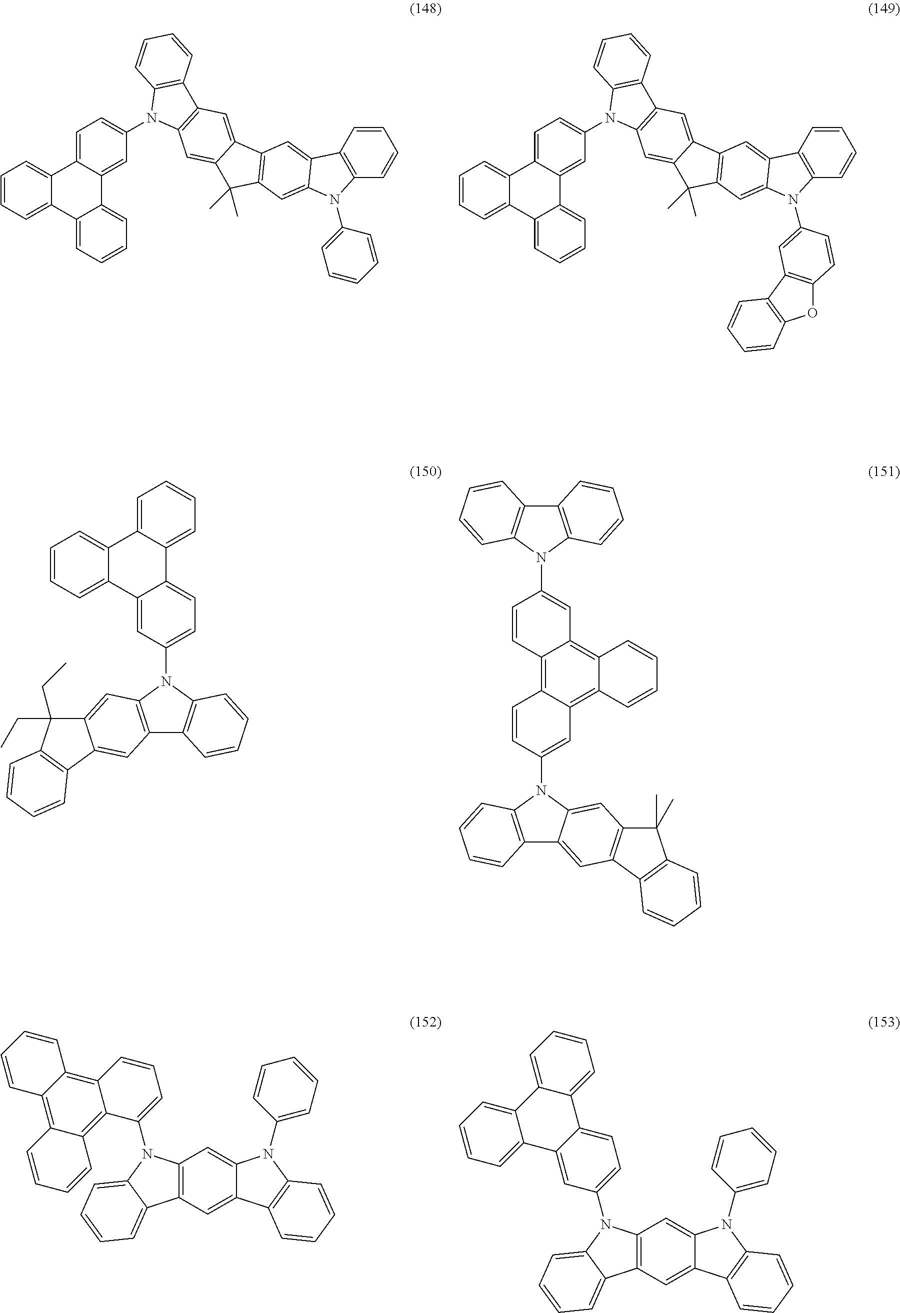 [SMILES: CC1(C)c2cc3c(cc2-c2cc4c5ccccc5n(-c5ccc6c7ccccc7c7ccccc7c6c5)c4cc21)c1ccccc1n3-c1ccccc1 ; CC1(C)c2cc3c(cc2-c2cc4c5ccccc5n(-c5ccc6c7ccccc7c7ccccc7c6c5)c4cc21)c1ccccc1n3-c1ccc2oc3ccccc3c2c1 ; CCC1(CC)c2ccccc2-c2cc3c4ccccc4n(-c4ccc5c6ccccc6c6ccccc6c5c4)c3cc21 ; CC1(C)c2ccccc2-c2cc3c4ccccc4n(-c4ccc5c6ccc(-n7c8ccccc8c8ccccc87)cc6c6ccccc6c5c4)c3cc21 ; c1ccc(-n2c3ccccc3c3cc4c5ccccc5n(-c5cccc6c7ccccc7c7ccccc7c56)c4cc32)cc1 ; c1ccc(-n2c3ccccc3c3cc4c5ccccc5n(-c5ccc6c7ccccc7c7ccccc7c6c5)c4cc32)cc1]

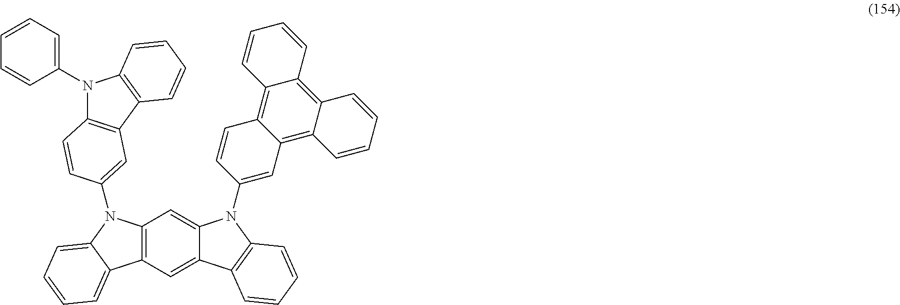 [SMILES: c1ccc(-n2c3ccccc3c3cc(-n4c5ccccc5c5cc6c7ccccc7n(-c7ccc8c9ccccc9c9ccccc9c8c7)c6cc54)ccc32)cc1]

There follows a detailed description of the organic electroluminescent device.

The organic electroluminescent device comprises cathode, anode and an emitting layer. Apart from these layers, it may comprise further layers, for example in each case one or more hole injection layers, hole transport layers, hole blocker layers, electron transport layers, electron injection layers, exciton blocker layers, electron blocker layers and/or charge generation layers. However, it should be pointed out that not necessarily every one of these layers need be present.

In the further layers of the inventive organic electroluminescent device, especially in the hole injection and transport layers and in the electron injection and transport layers, it is possible to use any materials as typically used according to the prior art. The hole transport layers may also be p-doped or the electron transport layers may also be n-doped. A p-doped layer is understood to mean a layer in which free holes are generated and which has increased conductivity as a result. A comprehensive discussion of doped transport layers in OLEDs can be found in Chem. Rev. 2007, 107, 1233. More preferably, the p-dopant is capable of oxidizing the hole transport material in the hole transport layer, i.e. has a sufficiently high redox potential, especially a higher redox potential than the hole transport material. Suitable dopants are in principle any compounds which are electron acceptor compounds and which can increase the conductivity of the organic layer by oxidizing the host. The person skilled in the art, in the context of his common knowledge in the art, is able to identify suitable compounds without any great effort. Especially suitable dopants are the compounds disclosed in WO 2011/073149, EP 1968131, EP 2276085, EP 2213662, EP 1722602, EP 2045848, DE 102007031220, U.S. Pat. No. 8,044,390, U.S. Pat. No. 8,057,712, WO 2009/003455, WO 2010/094378, WO 2011/120709 and US 2010/0096600.

The person skilled in the art will therefore be able, without exercising inventive skill, to use all the materials known for organic electroluminescent devices in combination with the emitting layer of the invention.

Preferred cathodes are metals having a low work function, metal alloys or multilayer structures composed of various metals, for example alkaline earth metals, alkali metals, main group metals or lanthanoids (e.g. Ca, Ba, Mg, Al, in, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. On the other hand, metal/metal oxide electrons (e.g. Al/Ni/NiOₓ, Al/PtOₓ) may also be preferred. In this case, at least one of the electrodes has to be transparent or semitransparent in order to enable the emission of light. A preferred structure uses a transparent anode. Preferred anode materials here are conductive mixed metal oxides. Particular preference is given to indium tin oxide (ITO) or indium zinc oxide (IZO). Preference is further given to conductive doped organic materials, especially conductive doped polymers.

The device is correspondingly (according to the application) structured, contact-connected and finally hermetically sealed, since the lifetime of such devices is severely shortened in the presence of water and/or air.

Additionally preferred is an organic electroluminescent device, wherein one or more layers are coated by a sublimation process. In this case, the materials are applied by vapor deposition in vacuum sublimation systems at an initial pressure of less than 10⁻⁵ mbar, preferably less than 10⁻⁶ mbar. It is also possible that the initial pressure is even lower, for example less than 10⁻⁷ mbar.

Preference is likewise given to an organic electroluminescent device, wherein one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and thus structured (for example, M. S. Arnold et al., Appl. Phys. Lett. 2008, 92, 053301).

Preference is additionally given to an organic electroluminescent device, wherein one or more layers are produced from solution, for example by spin-coating, or by any printing method, for example screen printing, flexographic printing, offset printing, LITI (light-induced thermal imaging, thermal transfer printing), inkjet printing or nozzle printing. For this purpose, soluble compounds are needed, which are obtained, for example, through suitable substitution. These methods are especially also suitable for oligomers, dendrimers and polymers.

These methods are known in general terms to those skilled in the art and can be applied by those skilled in the art without exercising inventive skill to organic electroluminescent devices comprising the compounds of the invention.

The present invention therefore further provides a process for producing an inventive organic electroluminescent device, wherein at least one layer is applied by a sublimation method and/or in that at least one layer is applied by an OVPD (organic vapor phase deposition) method or with the aid of a carrier gas sublimation and/or in that at least one layer is applied from solution, by spin-coating or by a printing method.

The organic electroluminescent devices of the invention are notable for one or more of the following surprising advantages over the prior art:
1. The organic electroluminescent devices of the invention have a very good and improved efficiency over devices according to the prior art that likewise exhibit TADF.
2. The organic electroluminescent devices of the invention have a very low voltage.
3. The organic electroluminescent devices of the invention have an improved lifetime over devices according to the prior art that likewise exhibit TADF.
4. Compared to organic electroluminescent devices according to the prior art that comprise iridium or platinum complexes as emitting compounds, the electroluminescent devices of the invention have an improved lifetime at elevated temperature.

These abovementioned advantages are not accompanied by a deterioration in the further electronic properties.

The invention is illustrated in detail by the examples which follow, without any intention of restricting it thereby. The person skilled in the art will be able to use the information given to execute the invention over the entire scope disclosed and produce further inventive organic electroluminescent devices without exercising inventive skill.

### EXAMPLES

### Determination of HOMO, LUMO, Singlet Level and Triplet Level

The HOMO and LUMO energy levels and the energy of the lowest triplet state T₁ and of the lowest excited singlet state S₁ of the materials are determined via quantum-chemical calculations. For this purpose, the “Gaussian09W” (Gaussian Inc.) software package is used. For calculation of organic substances without metals (referred to in table 4 by the “org.” method), an optimization of geometry is first conducted by the “Ground State/Semi-empirical/Default Spin/AM1/Charge 0/Spin Singlet” method. Subsequently, an energy calculation is effected on the basis of the optimized geometry. This is done using the “TD-SFC/DFT/Default Spin/B3PW91” method with the “6-31G(d)” basis set (charge 0, spin singlet). For metal-containing compounds (referred to in table 4 by the “M-org,” method), the geometry is optimized via the “Ground State/Hartree-Fock/Default Spin/LanL2 MB/Charge 0/Spin Singlet” method. The energy calculation is effected analogously to the organic substances, as described above, except that the “LanL2DZ” basis set is used for the metal atom and the “6-31 G(d)” basis set for the ligands. The HOMO energy level HEh or LUMO energy level LEh is obtained from the energy calculation in Hartree units. This is used to determine the HOMO and LUMO energy levels in electron volts, calibrated by cyclic voltammetry measurements, as follows:

HOMO(eV)=((HEh*27.212)−0.9899)/1.1206

LUMO(eV)=((LEh*27.212)−2.0041)/1.385

These values are to be regarded as HOMO and LUMO energy levels of the materials in the context of this application.

The lowest triplet state T₁ is defined as the energy of the triplet state having the lowest energy, which is apparent from the quantum-chemical calculation described.

The lowest excited singlet state S₁ is defined as the energy of the excited singlet state having the lowest energy, which is apparent from the quantum-chemical calculation described.

Table 4 states the HOMO and LUMO energy levels and S₁ and T₁ of the various materials.

Determination of Photoluminescence Quantum Efficiency (PLQE)

A 50 nm-thick film of the emission layers used in the different OLEDs is applied to a suitable transparent substrate, preferably quartz, meaning that the layer contains the same materials in the same concentration as in the OLED. This is done using the same production conditions as in the production of the emission layer for the OLEDs. An absorption spectrum of this film is measured in the wavelength range of 350-500 nm. For this purpose, the reflection spectrum R(λ) and the transmission spectrum T(λ) of the sample are determined at an angle of incidence of 6° (i.e. incidence virtually at right angles). The absorption spectrum in the context of this application is defined as A(λ)=1−R(λ)−T(λ).

If A(λ)≦0.3 in the range of 350-500 nm, the wavelength corresponding to the maximum of the absorption spectrum in the range of 350-500 nm is defined as λ_{exc}. If, for any wavelength, A(λ)>0.3, λ_{exc} is defined as being the greatest wavelength at which A(λ) changes from a value of less than 0.3 to a value of greater than 0.3 or from a value of greater than 0.3 to a value of less than 0.3.

The PLQE is determined using a Hamamatsu C9920-02 measurement system. The principle is based on the excitation of the sample with light of a defined wavelength and the measurement of the radiation absorbed and emitted. During the measurement, the sample is within an Ulbricht sphere (“integrating sphere”). The spectrum of the excitation light is approximately Gaussian with a half-height width of <10 nm and a peak wavelength λ_{exc} as defined above,

The PLQE is determined by the evaluation method customary for said measurement system. It should be strictly ensured that the sample does not come into contact with oxygen at any time, since the PLQE of materials having a small energy gap between S₁ and T₁ is very greatly reduced by oxygen (H. Uoyama et al., Nature 2012, Vol. 492, 234).

Table 2 states the PLQE for the emission layers of the OLEDs as defined above together with the excitation wavelength used.

Determination of Decay Time

The decay time is determined using a sample which is produced as described above under “Determination of the PL quantum efficiency (PLQE)”. The sample is excited at a temperature of 295 K by a laser pulse (wavelength 266 nm, pulse duration 1.5 ns, pulse energy 200 μJ, beam diameter 4 mm). At this time, the sample is under reduced pressure (<10⁻⁵ mbar). After excitation (defined as t=0), the profile of the intensity of the photoluminescence emitted against time is measured. The photoluminescence exhibits a steep drop at the start, which is attributable to the prompt fluorescence of the TADF compound. Later on, a slower drop is observed, delayed fluorescence (see, for example, H. Uoyama et al., Nature, vol. 492, no. 7428, pp. 234-238, 2012 and K. Masui et al., Organic Electronics, vol. 14, no. 11, pp. 2721-2726, 2013). The decay time tₐ in the context of this application is the decay time of the delayed fluorescence and is determined as follows: A time t_{d} at which the prompt fluorescence has abated to well below the intensity of the delayed fluorescence (<1%) is chosen, such that the determination of the decay time that follows is not affected thereby. This choice can be made by a person skilled in the art. For the measurement data from the time t_{d}, the decay time tₐ=tₑ−t_{d} is determined. In this formula, tₑ is that time after t=t_{d} at which the intensity has for the first time dropped to 1/e of its value at t=t_{d}.

Table 2 shows the values of tₐ and t_{d} which are determined for the emission layers of the OLEDs of the invention.

### Examples: Production of the OLEDs

In examples C1 to 16 which follow (see tables 1 and 2), the data of various OLEDs are presented.

The synthesis of the TP compound H1 of the formula (13) is described, for example, in EP1888708, H2 of the formula (25) and H3 of the formula (26), for example, in WO 2009021126, H4 of the formula (40) in WO 2010132524, H5 of the formula (126) in KR20110041729, and H6 of the formula (90), for example, in WO 2013056776. The synthesis of the TADF compound D1 is disclosed in Uoyama, K. Goushi, K. Shizu, H. Nomura and C. Adachi, “Highly efficient organic light-emitting diodes from delayed fluorescence,” Nature, vol. 492, no. 7428, pp. 234-238, December 2012.

Glass plaques coated with structured ITO (indium tin oxide) of thickness 50 nm are subjected to wet cleaning (laboratory glass washer, Merck Extran detergent), then baked in a nitrogen atmosphere at 250° C. for 15 min and, prior to coating, treated with an oxygen plasma for 130 s. These plasma-treated glass plaques form the substrates to which the OLEDs are applied. The substrates remain under reduced pressure prior to coating. The coating begins no later than 10 min after the plasma treatment.

The OLEDs basically have the following layer structure: substrate/hole transport layer (HTL)/emission layer (EML)/hole blocker layer (HBL)/electron transport layer (ETL) and finally a cathode. The cathode is formed by an aluminum layer of thickness 100 nm. The exact structure of the OLEDs can be found in table 1. The materials required for production of the OLEDs are shown in table 3.

All materials are applied by thermal vapor deposition in a vacuum chamber. The emission layer always consists of a matrix material (host material) and the emitting TADF compound, i.e. the material that exhibits a small energy gap between S₁ and T₁. The latter is added to the matrix material in a particular proportion by volume by coevaporation. Details given in such a form as CBP:D1 (95%:5%) mean here that the material CBP is present in the layer in a proportion by volume of 95% and D1 in a proportion of 5%. Analogously, the electron transport layer may also consist of a mixture of two materials.

The OLEDs are characterized in a standard manner. For this purpose, the electroluminescence spectra, the current efficiency (measured in cd/A), the power efficiency (measured in lm/W) and the external quantum efficiency (EQE, measured in percent) as a function of luminance, calculated from current-voltage-luminance characteristics (IUL characteristics) assuming Lambertian radiation characteristics, and also the lifetime are determined. The electroluminescence spectra are determined at a luminance of 1000 cd/m², and the CIE 1931 x and y color coordinates are calculated therefrom. The parameter U1000 in table 2 refers to the voltage which is required for a luminance of 1000 cd/m². CE1000 and PE1000 respectively refer to the current and power efficiencies which are achieved at 1000 cd/m². Finally, EQE1000 refers to the external quantum efficiency at an operating luminance of 1000 cd/m².

The lifetime LT is defined as the time after which the luminance drops from the starting luminance to a certain proportion L1 in the course of operation with constant current. Figures of j0=10 mA/cm², L1=80% in table 2 mean that the luminance in the course of operation at 10 mA/cm² falls to 80% of its starting value after the time LT.

The emitting dopant used in the emission layer is compound D1 which has an energy gap between S₁ and T₁ of 0.09 eV.

The data for the various OLEDs are collated in table 2. Example C1 is a comparative example according to the prior art; examples I1-I6 show data of OLEDs of the invention.

As can be inferred from the table, distinct improvements with regard to voltage and/or efficiency and/or lifetime over the prior art are obtained with emission layers of the invention. More particularly, it is possible to more than double the lifetime with compound H3 as matrix material compared to CBP; with compound H6, a better voltage by 0.5 V and a 40% improvement in efficiency are obtained.

TABLE 1
Structure of the OLEDs

| | HTL | EML | HBL | ETL |
|---|---|---|---|---|
| Ex. | thickness | thickness | thickness | thickness |
| C1 | SpMA1 | CBP:D1 (95%:5%) | IC1 | ST2:LiQ |
| | 90 nm | 15 nm | 10 nm | (50%:50%) 40 nm |
| I1 | SpMA1 | H1:D1 (95%:5%) | IC1 | ST2:LiQ |
| | 90 nm | 15 nm | 10 nm | (50%:50%) 40 nm |
| I2 | SpMA1 | H2:D1 (95%:5%) | IC1 | ST2:LiQ |
| | 90 nm | 15 nm | 10 nm | (50%:50%) 40 nm |
| I3 | SpMA1 | H3:D1 (95%:5%) | IC1 | ST2:LiQ |
| | 90 nm | 15 nm | 10 nm | (50%:50%) 40 nm |
| I4 | SpMA1 | H4:D1 (95%:5%) | IC1 | ST2:LiQ |
| | 90 nm | 15 nm | 10 nm | (50%:50%) 40 nm |
| I5 | SpMA1 | H5:D1 (95%:5%) | IC1 | ST2:LiQ |
| | 90 nm | 15 nm | 10 nm | (50%:50%) 40 nm |
| I6 | SpMA1 | H6:D1 (95%:5%) | IC1 | ST2:LiQ |
| | 90 nm | 15 nm | 10 nm | (50%:50%) 40 nm |

TABLE 2
Data of the OLEDs

| | U1000 | CE1000 | PE1000 | EQE | CIE x/y at | j0 | L1 | LT | PLQE | λ_{exc} | t_{d} | tₐ |
|---|---|---|---|---|---|---|---|---|---|---|---|---|
| Ex. | (V) | (cd/A) | (lm/W) | 1000 | 1000 cd/m² | mA/cm² | % | (h) | % | nm | μs | μs |
| C1 | 4.2 | 43 | 32 | 13.7% | 0.25/0.58 | 10 | 80 | 22 | 100 | 350 | 7 | 4.5 |
| I1 | 4.2 | 47 | 35 | 15.0% | 0.25/0.58 | 10 | 80 | 27 | 93 | 350 | 6 | 4.7 |
| I2 | 3.7 | 44 | 37 | 13.6% | 0.27/0.59 | 10 | 80 | 43 | 83 | 350 | 6 | 4.4 |
| I3 | 4.1 | 38 | 29 | 12.3% | 0.25/0.58 | 10 | 80 | 53 | 86 | 350 | 4 | 4.8 |
| I4 | 3.8 | 49 | 41 | 15.3% | 0.27/0.58 | 10 | 80 | 17 | 90 | 350 | 7 | 5.0 |
| I5 | 4.0 | 41 | 32 | 12.6% | 0.32/0.58 | 10 | 80 | 28 | 96 | 350 | 7 | 5.6 |
| I6 | 3.7 | 60 | 51 | 19.3% | 0.25/0.57 | 10 | 80 | 31 | 95 | 350 | 5 | 4.3 |

TABLE 3
Structural formulae of the materials for the OLEDs.
The compounds H1 to H6 correspond to the above-listed
formulae (13), (25), (26), (40), (126) and (90).

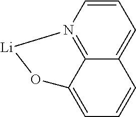

LiQ

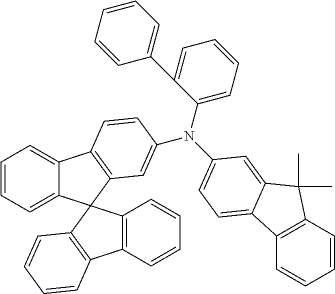 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

SpMA1

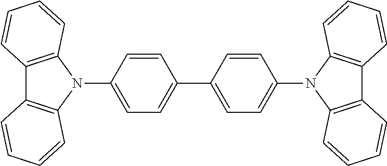 [SMILES: c1ccc2c(c1)c1ccccc1n2-c1ccc(-c2ccc(-n3c4ccccc4c4ccccc43)cc2)cc1]

CBP

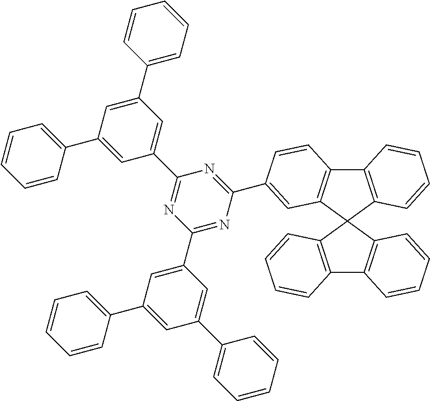 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ST2

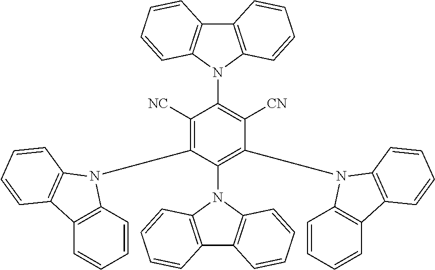 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

D1

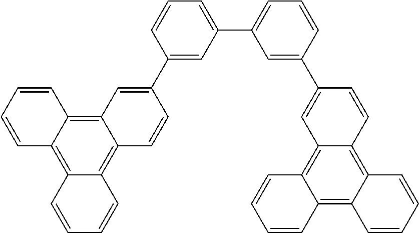 [SMILES: c1cc(-c2cccc(-c3ccc4c5ccccc5c5ccccc5c4c3)c2)cc(-c2ccc3c4ccccc4c4ccccc4c3c2)c1]

H1

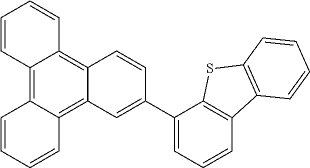 [SMILES: c1ccc2c(c1)sc1c(-c3ccc4c5ccccc5c5ccccc5c4c3)cccc12]

H2

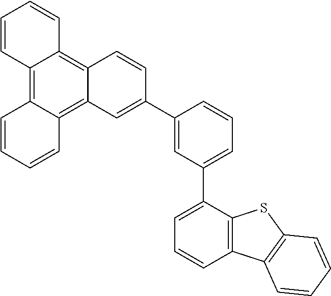 [SMILES: c1cc(-c2ccc3c4ccccc4c4ccccc4c3c2)cc(-c2cccc3c2sc2ccccc23)c1]

H3

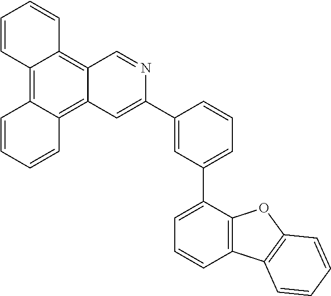 [SMILES: c1cc(-c2cc3c4ccccc4c4ccccc4c3cn2)cc(-c2cccc3c2oc2ccccc23)c1]

H4

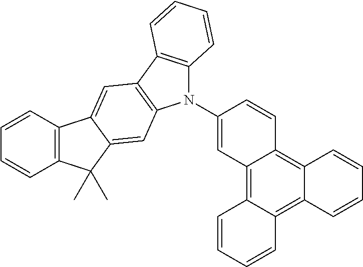 [SMILES: CC1(C)c2ccccc2-c2cc3c4ccccc4n(-c4ccc5c6ccccc6c6ccccc6c5c4)c3cc21]

H5

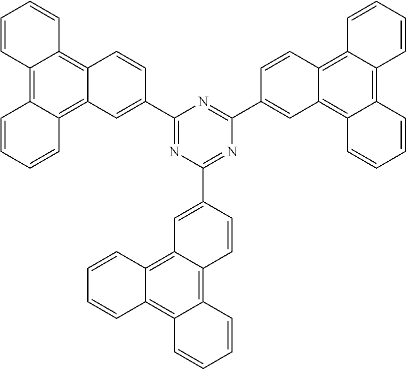 [SMILES: c1ccc2c(c1)c1ccccc1c1cc(-c3nc(-c4ccc5c6ccccc6c6ccccc6c5c4)nc(-c4ccc5c6ccccc6c6ccccc6c5c4)n3)ccc21]

H6

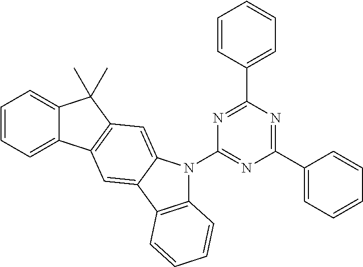 [SMILES: CC1(C)c2ccccc2-c2cc3c4ccccc4n(-c4nc(-c5ccccc5)nc(-c5ccccc5)n4)c3cc21]

IC1

TABLE 4
HOMO, LUMO, T₁, S₁ of the relevant materials

| | | HOMO | LUMO | S₁ | T₁ |
|---|---|---|---|---|---|
| Material | Method | (eV) | (eV) | (eV) | (eV) |
| D1 | org. | −6.11 | −3.40 | 2.50 | 2.41 |
| CBP | org. | −5.67 | −2.38 | 3.59 | 3.11 |
| IC1 | org. | −5.79 | −2.83 | 3.09 | 2.69 |
| H1 | org. | −6.06 | −2.39 | 3.43 | 2.70 |
| H2 | org. | −5.93 | −2.46 | 3.49 | 2.66 |
| H3 | org. | −6.01 | −2.39 | 3.46 | 2.70 |
| H4 | org. | −6.00 | −2.11 | 3.41 | 2.69 |
| H5 | org. | −5.53 | −2.39 | 3.27 | 2.68 |
| H6 | org. | −6.29 | −2.90 | 3.22 | 2.63 |

1.-15. (canceled)

16. An organic electroluminescent device comprising cathode, anode and emitting layer, comprising the following compounds:
(A) at least one luminescent organic compound having a gap between the lowest triplet state T₁ and the first excited singlet state S₁ of ≦0.15 eV (TADF compound); and
(B) at least one organic compound having at least one triphenylene group and/or one azatriphenylene group having up to six aza nitrogen atoms (TP compound).

17. The organic electroluminescent device as claimed in claim 16, wherein the TADF compound in a mixed layer with the TP compound has a luminescence quantum efficiency of at least 40%.

18. The organic electroluminescent device as claimed in claim 16, wherein the separation between S₁ and T₁ of the TADF compound is ≦0.10 eV.

19. The organic electroluminescent device as claimed in claim 16, wherein the separation between S₁ and T₁ of the TADF compound ≦0.08 eV.

20. The organic electroluminescent device as claimed in claim 16, wherein the separation between S₁ and T₁ of the TADF compound is ≦0.05 eV.

21. The organic electroluminescent device as claimed in claim 16, wherein the TADF compound is an aromatic compound having both donor and acceptor substituents.

22. The organic electroluminescent device as claimed in claim 16, wherein the following condition applies to the LUMO of the TADF compound LUMO(TADF) and the HOMO of the TP compound HOMO(matrix):
LUMO(TADF)−HOMO(matrix)>S₁(TADF)−0.4 eV,
where S₁(TADF) is the first excited singlet state S₁ of the TADF compound.

23. The organic electroluminescent device as claimed in claim 16, wherein the lowest triplet energy of the TP compound is not more than 0.1 eV lower than the lowest triplet energy of the TADF compound.

24. The organic electroluminescent device as claimed in claim 16, wherein the TP compound has the formula (1) or (2) 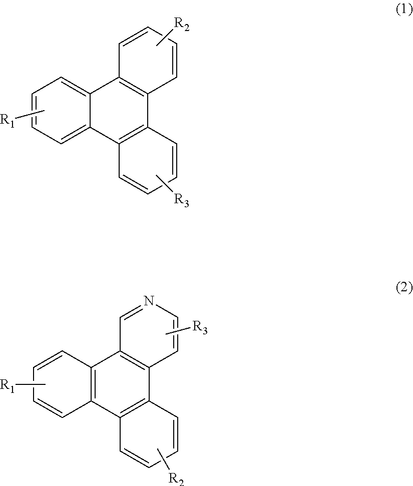
or wherein the TP compound corresponds to the formula (2) and has up to five further aza nitrogen atoms which replace C—H groups in the monoazatriphenylene group shown in formula (2),
where the R₁, R₂ and R₃ radicals are selected independently of one another,
where no, one or more R₁, R₂ or R₃ radicals may be present in each case, where two or more radicals of R₁, of R₂ or of R₃ are selected independently of one another,
where the R₁, R₂ or R₃ radicals are selected from
(i) an aromatic group which forms a conjugated system with the triphenylene group or azatriphenylene group, where the aromatic group has 5 to 80 aromatic ring atoms which may be substituted by one or more R₄ radicals, where R₄ is independently selected from H, D, F, Cl, Br, unbranched alkyl having 1 to 20 carbon atoms, branched or cyclic alkyl having 3 to 20 carbon atoms, where two or more R₄ radicals may be joined to one another and may form a ring, and
(ii) an alkyl radical R₅ selected from unbranched alkyl having 1 to 20 carbon atoms, branched or cyclic alkyl having 3 to 20 carbon atoms, where two R₅ radicals may be joined to one another and may form a ring,
with the proviso that at least one R₁, R₂ or R₃ radical which is an aromatic group (i) is present.

25. The organic electroluminescent device as claimed in claim 24, wherein R₁, R₂ or R₃ is bonded to the triphenylene group or azatriphenylene group via a conjugated C—C single bond; and/or
where R₁, R₂ and/or R₃ is or has an aromatic group fused to the triphenylene group and/or azatriphenylene group.

26. The organic electroluminescent device as claimed in claim 24, wherein the TP compound has at least one of the following structural units: 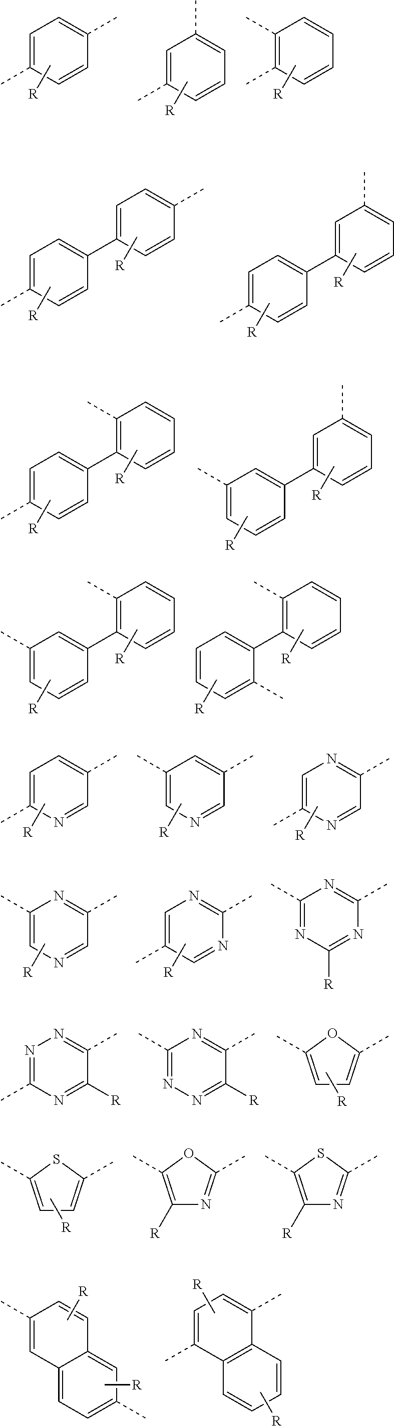 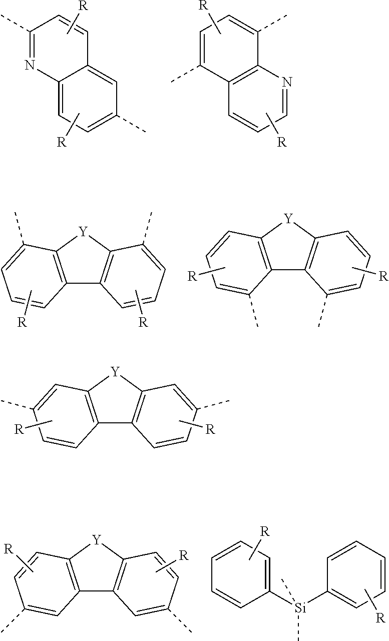
where R is selected as specified for R₄ in claim 22, or where R is an aromatic group which may be substituted by one or more R₄ radicals,
where Y is selected from C(R₆)₂, NR₆, S, O and Se, where R₆ is selected from H, unbranched alkyl having 1 to 20 carbon atoms, branched or cyclic alkyl having 3 to 20 carbon atoms, and an aromatic group which may be an aryl or heteroaryl group, where two R₆ radicals may be joined to one another and may form a ring, and
where the dotted lines represent single bonds.

27. The organic electroluminescent device as claimed in claim 24, wherein Y is selected from C(R₆)₂, NR₆, S, O and Se, where R₆ is selected from H, unbranched alkyl having 1 to carbon atoms, branched or cyclic alkyl having 3 to 20 carbon atoms, and an aromatic group which may be an phenyl group, where two R₆ radicals may be joined to one another and may form a ring,

28. The organic electroluminescent device as claimed in claim 24, wherein at least one R₁, R₂ or R₃ radical has a structural unit selected from the group consisting of phenyl, naphthyl, biphenyl, benzofuran, benzothiophene, carbazole, azacarbazole, dibenzothiophene, dibenzofuran, triphenylene and azines.

29. The organic electroluminescent device as claimed in claim 24, wherein at least one R₁, R₂ or R₃ radical has a structural unit selected from the group consisting of triazine, pyrimidine and pyridine.

30. The organic electroluminescent device as claimed in claim 24, wherein at least one R₁, R₂ or R₃ radical has an electron-donating group that exerts a +M effect.

31. The organic electroluminescent device as claimed in claim 30, wherein the electron-donating group is an electron-rich heteroaryl group having a heteroatom selected from N, O, S and Se.

32. The organic electroluminescent device as claimed in claim 24, wherein at least one R₁, R₂ or R₃ radical has an electron-withdrawing group that exerts a −M effect.

33. The organic electroluminescent device as claimed in claim 16, wherein the TP compound does not have any electron-withdrawing substituent that exerts a −M effect.

34. A process for producing the organic electroluminescent device as claimed in claim 16, which comprises applying at least one layer by a sublimation method and/or at least one layer is applied by an OVPD method or with the aid of a carrier gas sublimation and/or at least one layer is applied from solution, by spin-coating or by a printing method.
